(19) United States
(12) Patent Application Publication
(10) Pub. No.: US 2025/0323753 A1
(43) Pub. Date: Oct. 16, 2025

(54) POLAR CODING WITH EFFICIENT POLARIZATION

(71) Applicant: QUALCOMM Incorporated, San Diego, CA (US)

(72) Inventors: Seyyed Ali HASHEMI, San Jose, CA (US); Hobin KIM, San Diego, CA (US); Hari SANKAR, San Diego, CA (US); Wei YANG, San Diego, CA (US); Kirill IVANOV, La Jolla, CA (US); Jing JIANG, San Diego, CA (US)

(21) Appl. No.: 18/631,995

(22) Filed: Apr. 10, 2024

(51) Int. Cl. H04L 1/00

(52) U.S. Cl. CPC H04L 1/0061; H04L 1/0052

(57) ABSTRACT

Polar coding with efficient polarization and dynamic decoding order is described. An apparatus is configured to partition a set of bits into at least two subsets of bits based on a bit weighting metric. The set of bits is associated with a polar encoding and a set of information bits and a set of frozen bits. The apparatus is configured to generate a set of decoded bits based on a decoding of each bit in the set of bits according to a bit priority. The bit priority is based on a first error metric of each bit in the set of bits for a first number of ordered permutations of bits associated with the at least two subsets of bits. The apparatus is configured to transmit, for a second network device, a set of encoded bits that are based on an encoding of the set of decoded bits.

### TECHNICAL FIELD

The present disclosure relates generally to communication systems, and more particularly, to wireless communications utilizing polar codes.

### INTRODUCTION

Wireless communication systems are widely deployed to provide various telecommunication services such as telephony, video, data, messaging, and broadcasts. Typical wireless communication systems may employ multiple-access technologies capable of supporting communication with multiple users by sharing available system resources. Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example telecommunication standard is 5G New Radio (NR). 5G NR is part of a continuous mobile broadband evolution promulgated by Third Generation Partnership Project (3GPP) to meet new requirements associated with latency, reliability, security, scalability (e.g., with Internet of Things (IoT)), and other requirements. 5G NR includes services associated with enhanced mobile broadband (eMBB), massive machine type communications (mMTC), and ultra-reliable low latency communications (URLLC). Some aspects of 5G NR may be based on the 4G Long Term Evolution (LTE) standard. There exists a need for further improvements in 5G NR technology. These improvements may also be applicable to other multi-access technologies and the telecommunication standards that employ these technologies.

### BRIEF SUMMARY

The following presents a simplified summary of one or more aspects in order to provide a basic understanding of such aspects. This summary is not an extensive overview of all contemplated aspects. This summary neither identifies key or critical elements of all aspects nor delineates the scope of any or all aspects. Its sole purpose is to present some concepts of one or more aspects in a simplified form as a prelude to the more detailed description that is presented later.

In an aspect of the disclosure, a method, a computer-readable medium, and an apparatus are provided. The apparatus is configured to partition a set of bits into at least two subsets of bits based on a bit weighting metric, where the set of bits is associated with a polar encoding and a set of information bits and a set of frozen bits. The apparatus is configured to generate a set of decoded bits based on a decoding of each bit in the set of bits according to a bit priority, where the bit priority is based on a first error metric of each bit in the set of bits for a first number of ordered permutations of bits associated with the at least two subsets of bits. The apparatus is configured to transmit, for a second network device, a set of encoded bits that are based on an encoding of the set of decoded bits.

In the aspects, the method includes partitioning a set of bits into at least two subsets of bits based on a bit weighting metric, where the set of bits is associated with a polar encoding and a set of information bits and a set of frozen bits. The method includes generating a set of decoded bits based on a decoding of each bit in the set of bits according to a bit priority, where the bit priority is based on a first error metric of each bit in the set of bits for a first number of ordered permutations of bits associated with the at least two subsets of bits. The method includes transmitting, for a second network device, a set of encoded bits that are based on an encoding of the set of decoded bits.

To the accomplishment of the foregoing and related ends, the one or more aspects may include the features hereinafter fully described and particularly pointed out in the claims. The following description and the drawings set forth in detail certain illustrative features of the one or more aspects. These features are indicative, however, of but a few of the various ways in which the principles of various aspects may be employed.

### BRIEF DESCRIPTION OF THE DRAWINGS

FIG. 1 is a diagram illustrating an example of a wireless communications system and an access network.

FIG. 2A is a diagram illustrating an example of a first frame, in accordance with various aspects of the present disclosure.

FIG. 2B is a diagram illustrating an example of downlink (DL) channels within a subframe, in accordance with various aspects of the present disclosure.

FIG. 2C is a diagram illustrating an example of a second frame, in accordance with various aspects of the present disclosure.

FIG. 2D is a diagram illustrating an example of uplink (UL) channels within a subframe, in accordance with various aspects of the present disclosure.

FIG. 3 is a diagram illustrating an example of a base station and user equipment (UE) in an access network.

FIG. 4 is a diagram illustrating an example of a basic polar coding.

FIG. 5 is a call flow diagram for wireless communications, in accordance with various aspects of the present disclosure.

FIG. 6 is a diagram illustrating an example of polar coding with efficient polarization and dynamic decoding order, in accordance with various aspects of the present disclosure.

FIG. 7 is a diagram illustrating an example of polar coding with efficient polarization and dynamic decoding order, in accordance with various aspects of the present disclosure.

FIG. 8 is a diagram illustrating an example of polar coding with efficient polarization and dynamic decoding order, in accordance with various aspects of the present disclosure.

FIG. 9 is a flowchart of a method of wireless communication.

FIG. 10 is a flowchart of a method of wireless communication.

FIG. 11 is a diagram illustrating an example of a hardware implementation for an example apparatus and/or network entity.

FIG. 12 is a diagram illustrating an example of a hardware implementation for an example network entity.

### DETAILED DESCRIPTION

Wireless communication networks, such as a 5G NR network, among other examples of wireless communication networks, may be designed to support communications between network nodes (e.g., base stations, gNBs, etc.) and UEs, or transmitter network devices and receiver network devices, generally, that utilize polar codes for channel polarization of communication payloads. A polar code is based on the phenomenon of channel polarization, where communication channels, after applying the polar transform (e.g., with an Arikan kernel), may converge to either of a useless or a noiseless channel. Polar code design may include determining which bit locations are allocated to send information bits and which bit locations to send frozen bits. Successive-cancellation (SC) decoding (e.g., with a fixed decoding order) and SC list (SCL) decoding are common decoding algorithms that may be used for polar code implementations.

However, fixed decoding order solutions are limited to bit-by-bit sequential decoding of fixed-position bits in a block to be polar encoded for a communication payload. Such fixed order decoding lacks mechanisms to improve error probabilities for bits in communication payloads. Additionally, fixed order decoding may have issues with optimizations and enhancements such as decoder-specific optimizations through code construction for faster/more efficient polarization, extensibility to other types of decoding (e.g., list decoding), the implementation of cyclic redundancy check (CRC), scaling to blocks with larger numbers of bits for communication payloads, and avoidance of disproportionate decoding steps for increasing numbers of bits encoded.

Various aspects relate generally to wireless communications utilizing polar codes. Some aspects more specifically relate to polar coding with efficient polarization and dynamic decoding orders. In some examples, a network device partition a set of bits into at least two subsets of bits based on a bit weighting metric. The set of bits may be associated with a polar encoding and a set of information bits and a set of frozen bits, e.g., for a communication payload. The network device may generate a set of decoded bits based on a decoding of each bit in the set of bits according to a bit priority. The bit priority may be based on a first error metric of each bit in the set of bits for a first number of ordered permutations of bits associated with the at least two subsets of bits. The network device may transmit, for another network device, a set of encoded bits that are based on an encoding of the set of decoded bits.

Particular aspects of the subject matter described in this disclosure can be implemented to realize one or more of the following potential advantages. In some examples, by utilizing permutation-based polar decoding using automorphisms, the described techniques can be used to enable a polar code to be decoded with a different decoding order (that preserves the polar code, e.g., via automorphism ensemble decoding), and by which the decoding results may depend on the decoding order. In some examples, by utilizing permutation-based polar decoding using automorphisms, the described techniques can be used to enable a decoder to decode the same received signal in accordance with different decoding orders (e.g., permutations) and more efficiently identify the best result from specific subsets of these permutations. In some examples, by utilizing automorphism in polar code construction and decoder characteristics, the described techniques can be used to enable a polar decoder to perform a faster polarization than conventional polar codes.

The detailed description set forth below in connection with the drawings describes various configurations and does not represent the only configurations in which the concepts described herein may be practiced. The detailed description includes specific details for the purpose of providing a thorough understanding of various concepts. However, these concepts may be practiced without these specific details. In some instances, well known structures and components are shown in block diagram form in order to avoid obscuring such concepts.

Several aspects of telecommunication systems are presented with reference to various apparatus and methods. These apparatus and methods are described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. When multiple processors are implemented, the multiple processors may perform the functions individually or in combination. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software, whether referred to as software, firmware, middleware, microcode, hardware description language, or otherwise, shall be construed broadly to mean instructions, instruction sets, code, code segments, program code, programs, subprograms, software components, applications, software applications, software packages, routines, subroutines, objects, executables, threads of execution, procedures, functions, or any combination thereof.

Accordingly, in one or more example aspects, implementations, and/or use cases, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, such computer-readable media can include a random-access memory (RAM), a read-only memory (ROM), an electrically erasable programmable ROM (EEPROM), optical disk storage, magnetic disk storage, other magnetic storage devices, combinations of the types of computer-readable media, or any other medium that can be used to store computer executable code in the form of instructions or data structures that can be accessed by a computer.

While aspects, implementations, and/or use cases are described in this application by illustration to some examples, additional or different aspects, implementations and/or use cases may come about in many different arrangements and scenarios. Aspects, implementations, and/or use cases described herein may be implemented across many differing platform types, devices, systems, shapes, sizes, and packaging arrangements. For example, aspects, implementations, and/or use cases may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described examples may occur. Aspects, implementations, and/or use cases may range a spectrum from chip-level or modular components to non-modular, non-chip-level implementations and further to aggregate, distributed, or original equipment manufacturer (OEM) devices or systems incorporating one or more techniques herein. In some practical settings, devices incorporating described aspects and features may also include additional components and features for implementation and practice of claimed and described aspect. For example, transmission and reception of wireless signals necessarily includes a number of components for analog and digital purposes (e.g., hardware components including antenna, RF-chains, power amplifiers, modulators, buffer, processor(s), interleaver, adders/summers, etc.). Techniques described herein may be practiced in a wide variety of devices, chip-level components, systems, distributed arrangements, aggregated or disaggregated components, end-user devices, etc. of varying sizes, shapes, and constitution.

Deployment of communication systems, such as 5G NR systems, may be arranged in multiple manners with various components or constituent parts. In a 5G NR system, or network, a network node, a network entity, a mobility element of a network, a radio access network (RAN) node, a core network node, a network element, or a network equipment, such as a base station (BS), or one or more units (or one or more components) performing base station functionality, may be implemented in an aggregated or disaggregated architecture. For example, a BS (such as a Node B (NB), evolved NB (eNB), NR BS, 5G NB, access point (AP), a transmission reception point (TRP), or a cell, etc.) may be implemented as an aggregated base station (also known as a standalone BS or a monolithic BS) or a disaggregated base station.

An aggregated base station may be configured to utilize a radio protocol stack that is physically or logically integrated within a single RAN node. A disaggregated base station may be configured to utilize a protocol stack that is physically or logically distributed among two or more units (such as one or more central or centralized units (CUs), one or more distributed units (DUs), or one or more radio units (RUs)). In some aspects, a CU may be implemented within a RAN node, and one or more DUs may be co-located with the CU, or alternatively, may be geographically or virtually distributed throughout one or multiple other RAN nodes. The DUs may be implemented to communicate with one or more RUs. Each of the CU, DU and RU can be implemented as virtual units, i.e., a virtual central unit (VCU), a virtual distributed unit (VDU), or a virtual radio unit (VRU).

Base station operation or network design may consider aggregation characteristics of base station functionality. For example, disaggregated base stations may be utilized in an integrated access backhaul (IAB) network, an open radio access network (O-RAN (such as the network configuration sponsored by the O-RAN Alliance)), or a virtualized radio access network (vRAN, also known as a cloud radio access network (C-RAN)). Disaggregation may include distributing functionality across two or more units at various physical locations, as well as distributing functionality for at least one unit virtually, which can enable flexibility in network design. The various units of the disaggregated base station, or disaggregated RAN architecture, can be configured for wired or wireless communication with at least one other unit.

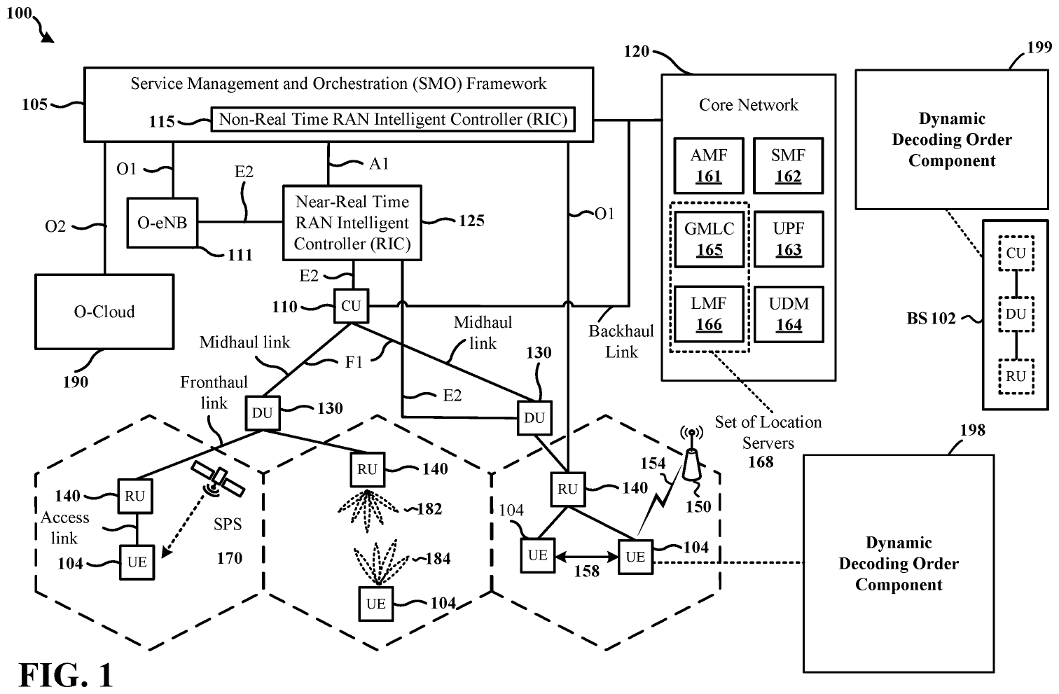

FIG. 1 is a diagram 100 illustrating an example of a wireless communications system and an access network. The illustrated wireless communications system includes a disaggregated base station architecture. The disaggregated base station architecture may include one or more CUs 110 that can communicate directly with a core network 120 via a backhaul link, or indirectly with the core network 120 through one or more disaggregated base station units (such as a Near-Real Time (Near-RT) RAN Intelligent Controller (RIC) 125 via an E2 link, or a Non-Real Time (Non-RT) RIC 115 associated with a Service Management and Orchestration (SMO) Framework 105, or both). A CU 110 may communicate with one or more DUs 130 via respective midhaul links, such as an F1 interface. The DUs 130 may communicate with one or more RUs 140 via respective fronthaul links. The RUs 140 may communicate with respective UEs 104 via one or more radio frequency (RF) access links. In some implementations, the UE 104 may be simultaneously served by multiple RUs 140.

Each of the units, i.e., the CUS 110, the DUs 130, the RUs 140, as well as the Near-RT RICs 125, the Non-RT RICs 115, and the SMO Framework 105, may include one or more interfaces or be coupled to one or more interfaces configured to receive or to transmit signals, data, or information (collectively, signals) via a wired or wireless transmission medium. Each of the units, or an associated processor or controller providing instructions to the communication interfaces of the units, can be configured to communicate with one or more of the other units via the transmission medium. For example, the units can include a wired interface configured to receive or to transmit signals over a wired transmission medium to one or more of the other units. Additionally, the units can include a wireless interface, which may include a receiver, a transmitter, or a transceiver (such as an RF transceiver), configured to receive or to transmit signals, or both, over a wireless transmission medium to one or more of the other units.

In some aspects, the CU 110 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 110. The CU 110 may be configured to handle user plane functionality (i.e., Central Unit-User Plane (CU-UP)), control plane functionality (i.e., Central Unit-Control Plane (CU-CP)), or a combination thereof. In some implementations, the CU 110 can be logically split into one or more CU-UP units and one or more CU-CP units. The CU-UP unit can communicate bidirectionally with the CU-CP unit via an interface, such as an E1 interface when implemented in an O-RAN configuration. The CU 110 can be implemented to communicate with the DU 130, as necessary, for network control and signaling.

The DU 130 may correspond to a logical unit that includes one or more base station functions to control the operation of one or more RUs 140. In some aspects, the DU 130 may host one or more of a radio link control (RLC) layer, a medium access control (MAC) layer, and one or more high physical (PHY) layers (such as modules for forward error correction (FEC) encoding and decoding, scrambling, modulation, demodulation, or the like) depending, at least in part, on a functional split, such as those defined by 3GPP. In some aspects, the DU 130 may further host one or more low PHY layers. Each layer (or module) can be implemented with an interface configured to communicate signals with other layers (and modules) hosted by the DU 130, or with the control functions hosted by the CU 110.

Lower-layer functionality can be implemented by one or more RUs 140. In some deployments, an RU 140, controlled by a DU 130, may correspond to a logical node that hosts RF processing functions, or low-PHY layer functions (such as performing fast Fourier transform (FFT), inverse FFT (IFFT), digital beamforming, physical random access channel (PRACH) extraction and filtering, or the like), or both, based at least in part on the functional split, such as a lower layer functional split. In such an architecture, the RU(s) 140 can be implemented to handle over the air (OTA) communication with one or more UEs 104. In some implementations, real-time and non-real-time aspects of control and user plane communication with the RU(s) 140 can be controlled by the corresponding DU 130. In some scenarios, this configuration can enable the DU(s) 130 and the CU 110 to be implemented in a cloud-based RAN architecture, such as a vRAN architecture.

The SMO Framework 105 may be configured to support RAN deployment and provisioning of non-virtualized and virtualized network elements. For non-virtualized network elements, the SMO Framework 105 may be configured to support the deployment of dedicated physical resources for RAN coverage requirements that may be managed via an operations and maintenance interface (such as an O1 interface). For virtualized network elements, the SMO Framework 105 may be configured to interact with a cloud computing platform (such as an open cloud (O-Cloud) 190) to perform network element life cycle management (such as to instantiate virtualized network elements) via a cloud computing platform interface (such as an O2 interface). Such virtualized network elements can include, but are not limited to, CUs 110, DUs 130, RUs 140 and Near-RT RICs 125. In some implementations, the SMO Framework 105 can communicate with a hardware aspect of a 4G RAN, such as an open eNB (O-eNB) 111, via an O1 interface. Additionally, in some implementations, the SMO Framework 105 can communicate directly with one or more RUs 140 via an O1 interface. The SMO Framework 105 also may include a Non-RT RIC 115 configured to support functionality of the SMO Framework 105.

The Non-RT RIC 115 may be configured to include a logical function that enables non-real-time control and optimization of RAN elements and resources, artificial intelligence (AI)/machine learning (ML) (AI/ML) workflows including model training and updates, or policy-based guidance of applications/features in the Near-RT RIC 125. The Non-RT RIC 115 may be coupled to or communicate with (such as via an A1 interface) the Near-RT RIC 125. The Near-RT RIC 125 may be configured to include a logical function that enables near-real-time control and optimization of RAN elements and resources via data collection and actions over an interface (such as via an E2 interface) connecting one or more CUs 110, one or more DUs 130, or both, as well as an O-eNB, with the Near-RT RIC 125.

In some implementations, to generate AI/ML models to be deployed in the Near-RT RIC 125, the Non-RT RIC 115 may receive parameters or external enrichment information from external servers. Such information may be utilized by the Near-RT RIC 125 and may be received at the SMO Framework 105 or the Non-RT RIC 115 from non-network data sources or from network functions. In some examples, the Non-RT RIC 115 or the Near-RT RIC 125 may be configured to tune RAN behavior or performance. For example, the Non-RT RIC 115 may monitor long-term trends and patterns for performance and employ AI/ML models to perform corrective actions through the SMO Framework 105 (such as reconfiguration via O1) or via creation of RAN management policies (such as A1 policies).

At least one of the CU 110, the DU 130, and the RU 140 may be referred to as a base station 102. Accordingly, a base station 102 may include one or more of the CU 110, the DU 130, and the RU 140 (each component indicated with dotted lines to signify that each component may or may not be included in the base station 102). The base station 102 provides an access point to the core network 120 for a UE 104. The base station 102 may include macrocells (high power cellular base station) and/or small cells (low power cellular base station). The small cells include femtocells, picocells, and microcells. A network that includes both small cell and macrocells may be known as a heterogeneous network. A heterogeneous network may also include Home Evolved Node Bs (eNBs) (HeNBs), which may provide service to a restricted group known as a closed subscriber group (CSG). The communication links between the RUs 140 and the UEs 104 may include uplink (UL) (also referred to as reverse link) transmissions from a UE 104 to an RU 140 and/or downlink (DL) (also referred to as forward link) transmissions from an RU 140 to a UE 104. The communication links may use multiple-input and multiple-output (MIMO) antenna technology, including spatial multiplexing, beamforming, and/or transmit diversity. The communication links may be through one or more carriers. The base station 102/UEs 104 may use spectrum up to Y MHz (e.g., 5, 10, 15, 20, 100, 400, etc. MHz) bandwidth per carrier allocated in a carrier aggregation of up to a total of Yx MHz (x component carriers) used for transmission in each direction. The carriers may or may not be adjacent to each other. Allocation of carriers may be asymmetric with respect to DL and UL (e.g., more or fewer carriers may be allocated for DL than for UL). The component carriers may include a primary component carrier and one or more secondary component carriers. A primary component carrier may be referred to as a primary cell (PCell) and a secondary component carrier may be referred to as a secondary cell (SCell).

Certain UEs 104 may communicate with each other using device-to-device (D2D) communication link 158. The D2D communication link 158 may use the DL/UL wireless wide area network (WWAN) spectrum. The D2D communication link 158 may use one or more sidelink channels, such as a physical sidelink broadcast channel (PSBCH), a physical sidelink discovery channel (PSDCH), a physical sidelink shared channel (PSSCH), and a physical sidelink control channel (PSCCH). D2D communication may be through a variety of wireless D2D communications systems, such as for example, Bluetooth™ (Bluetooth is a trademark of the Bluetooth Special Interest Group (SIG)), Wi-Fi™ (Wi-Fi is a trademark of the Wi-Fi Alliance) based on the Institute of Electrical and Electronics Engineers (IEEE) 802.11 standard, LTE, or NR.

The wireless communications system may further include a Wi-Fi AP 150 in communication with UEs 104 (also referred to as Wi-Fi stations (STAs)) via communication link 154, e.g., in a 5 GHz unlicensed frequency spectrum or the like. When communicating in an unlicensed frequency spectrum, the UEs 104/AP 150 may perform a clear channel assessment (CCA) prior to communicating in order to determine whether the channel is available.

The electromagnetic spectrum is often subdivided, based on frequency/wavelength, into various classes, bands, channels, etc. In 5G NR, two initial operating bands have been identified as frequency range designations FR1 (410 MHZ-7.125 GHZ) and FR2 (24.25 GHz-52.6 GHz). Although a portion of FR1 is greater than 6 GHz, FR1 is often referred to (interchangeably) as a “sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHZ-24.25 GHz). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR2-2 (52.6 GHz-71 GHZ), FR4 (71 GHz-114.25 GHz), and FR5 (114.25 GHZ-300 GHz). Each of these higher frequency bands falls within the EHF band.

With the above aspects in mind, unless specifically stated otherwise, the term “sub-6 GHz” or the like if used herein may broadly represent frequencies that may be less than 6 GHZ, may be within FR1, or may include mid-band frequencies. Further, unless specifically stated otherwise, the term “millimeter wave” or the like if used herein may broadly represent frequencies that may include mid-band frequencies, may be within FR2, FR4, FR2-2, and/or FR5, or may be within the EHF band.

The base station 102 and the UE 104 may each include a plurality of antennas, such as antenna elements, antenna panels, and/or antenna arrays to facilitate beamforming. The base station 102 may transmit a beamformed signal 182 to the UE 104 in one or more transmit directions. The UE 104 may receive the beamformed signal from the base station 102 in one or more receive directions. The UE 104 may also transmit a beamformed signal 184 to the base station 102 in one or more transmit directions. The base station 102 may receive the beamformed signal from the UE 104 in one or more receive directions. The base station 102/UE 104 may perform beam training to determine the best receive and transmit directions for each of the base station 102/UE 104. The transmit and receive directions for the base station 102 may or may not be the same. The transmit and receive directions for the UE 104 may or may not be the same.

The base station 102 may include and/or be referred to as a gNB, Node B, eNB, an access point, a base transceiver station, a radio base station, a radio transceiver, a transceiver function, a basic service set (BSS), an extended service set (ESS), a TRP, network node, network entity, network equipment, or some other suitable terminology. The base station 102 can be implemented as an integrated access and backhaul (IAB) node, a relay node, a sidelink node, an aggregated (monolithic) base station with a baseband unit (BBU) (including a CU and a DU) and an RU, or as a disaggregated base station including one or more of a CU, a DU, and/or an RU. The set of base stations, which may include disaggregated base stations and/or aggregated base stations, may be referred to as next generation (NG) RAN (NG-RAN).

The core network 120 may include an Access and Mobility Management Function (AMF) 161, a Session Management Function (SMF) 162, a User Plane Function (UPF) 163, a Unified Data Management (UDM) 164, one or more location servers 168, and other functional entities. The AMF 161 is the control node that processes the signaling between the UEs 104 and the core network 120. The AMF 161 supports registration management, connection management, mobility management, and other functions. The SMF 162 supports session management and other functions. The UPF 163 supports packet routing, packet forwarding, and other functions. The UDM 164 supports the generation of authentication and key agreement (AKA) credentials, user identification handling, access authorization, and subscription management. The one or more location servers 168 are illustrated as including a Gateway Mobile Location Center (GMLC) 165 and a Location Management Function (LMF) 166. However, generally, the one or more location servers 168 may include one or more location/positioning servers, which may include one or more of the GMLC 165, the LMF 166, a position determination entity (PDE), a serving mobile location center (SMLC), a mobile positioning center (MPC), or the like. The GMLC 165 and the LMF 166 support UE location services. The GMLC 165 provides an interface for clients/applications (e.g., emergency services) for accessing UE positioning information. The LMF 166 receives measurements and assistance information from the NG-RAN and the UE 104 via the AMF 161 to compute the position of the UE 104. The NG-RAN may utilize one or more positioning methods in order to determine the position of the UE 104. Positioning the UE 104 may involve signal measurements, a position estimate, and an optional velocity computation based on the measurements. The signal measurements may be made by the UE 104 and/or the base station 102 serving the UE 104. The signals measured may be based on one or more of a satellite positioning system (SPS) 170 (e.g., one or more of a Global Navigation Satellite System (GNSS), global position system (GPS), non-terrestrial network (NTN), or other satellite position/location system), LTE signals, wireless local area network (WLAN) signals, Bluetooth signals, a terrestrial beacon system (TBS), sensor-based information (e.g., barometric pressure sensor, motion sensor), NR enhanced cell ID (NR E-CID) methods, NR signals (e.g., multi-round trip time (Multi-RTT), DL angle-of-departure (DL-AoD), DL time difference of arrival (DL-TDOA), UL time difference of arrival (UL-TDOA), and UL angle-of-arrival (UL-AoA) positioning), and/or other systems/signals/sensors.

Examples of UEs 104 include a cellular phone, a smart phone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, a smart device, a wearable device, a vehicle, an electric meter, a gas pump, a large or small kitchen appliance, a healthcare device, an implant, a sensor/actuator, a display, or any other similar functioning device. Some of the UEs 104 may be referred to as IoT devices (e.g., parking meter, gas pump, toaster, vehicles, heart monitor, etc.). The UE 104 may also be referred to as a station, a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. In some scenarios, the term UE may also apply to one or more companion devices such as in a device constellation arrangement. One or more of these devices may collectively access the network and/or individually access the network.

Referring again to FIG. 1, in certain aspects, the UE 104 may have a dynamic decoding order component 198 (“component 198”) that may be configured to partition a set of bits into at least two subsets of bits based on a bit weighting metric, where the set of bits is associated with a polar encoding and a set of information bits and a set of frozen bits. The component 198 may be configured to generate a set of decoded bits based on a decoding of each bit in the set of bits according to a bit priority, where the bit priority is based on a first error metric of each bit in the set of bits for a first number of ordered permutations of bits associated with the at least two subsets of bits. The component 198 may be configured to transmit, for a second network device, a set of encoded bits that are based on an encoding of the set of decoded bits. The component 198 may be configured to output an indication of at least one of the set of generated decoded bits or the set of encoded bits.

In certain aspects, the base station 102 may have a dynamic decoding order component 199 (“component 199”) that may be configured to partition a set of bits into at least two subsets of bits based on a bit weighting metric, where the set of bits is associated with a polar encoding and a set of information bits and a set of frozen bits. The component 199 may be configured to generate a set of decoded bits based on a decoding of each bit in the set of bits according to a bit priority, where the bit priority is based on a first error metric of each bit in the set of bits for a first number of ordered permutations of bits associated with the at least two subsets of bits. The component 199 may be configured to transmit, for a second network device, a set of encoded bits that are based on an encoding of the set of decoded bits. The component 199 may be configured to output an indication of at least one of the set of generated decoded bits or the set of encoded bits.

Accordingly, aspects improve error probabilities for bits in communication payloads and provide for optimizations and enhancements such as decoder-specific optimizations through code construction for faster/more efficient polarization, extensibility to other types of decoding (e.g., list decoding), the implementation of CRC, scaling to blocks with larger numbers of bits for communication payloads, and avoidance of disproportionate decoding steps for increasing numbers of bits encoded.

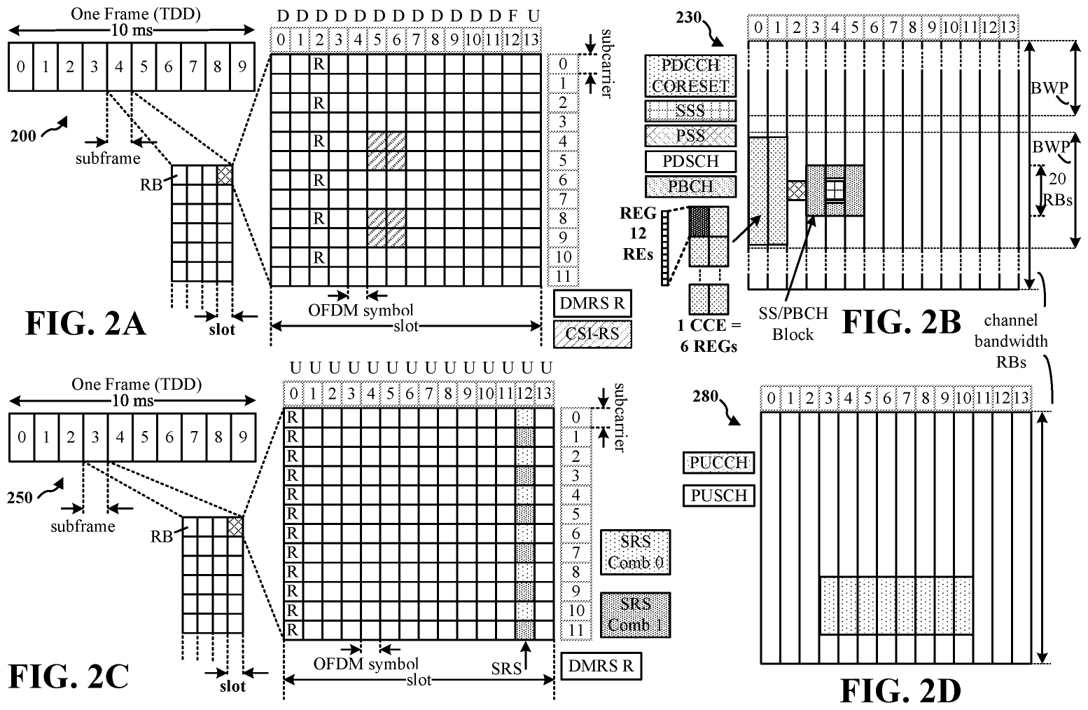

FIG. 2A is a diagram 200 illustrating an example of a first subframe within a 5G NR frame structure. FIG. 2B is a diagram 230 illustrating an example of DL channels within a 5G NR subframe. FIG. 2C is a diagram 250 illustrating an example of a second subframe within a 5G NR frame structure. FIG. 2D is a diagram 280 illustrating an example of UL channels within a 5G NR subframe. The 5G NR frame structure may be frequency division duplexed (FDD) in which for a particular set of subcarriers (carrier system bandwidth), subframes within the set of subcarriers are dedicated for either DL or UL, or may be time division duplexed (TDD) in which for a particular set of subcarriers (carrier system bandwidth), subframes within the set of subcarriers are dedicated for both DL and UL. In the examples provided by FIGS. 2A, 2C, the 5G NR frame structure is assumed to be TDD, with subframe 4 being configured with slot format 28 (with mostly DL), where D is DL, U is UL, and F is flexible for use between DL/UL, and subframe 3 being configured with slot format 1 (with all UL). While subframes 3, 4 are shown with slot formats 1, 28, respectively, any particular subframe may be configured with any of the various available slot formats 0-61. Slot formats 0, 1 are all DL, UL, respectively. Other slot formats 2-61 include a mix of DL, UL, and flexible symbols. UEs are configured with the slot format (dynamically through DL control information (DCI), or semi-statically/statically through radio resource control (RRC) signaling) through a received slot format indicator (SFI). Note that the description infra applies also to a 5G NR frame structure that is TDD.

FIGS. 2A-2D illustrate a frame structure, and the aspects of the present disclosure may be applicable to other wireless communication technologies, which may have a different frame structure and/or different channels. A frame (10 ms) may be divided into 10 equally sized subframes (1 ms). Each subframe may include one or more time slots. Subframes may also include mini-slots, which may include 7, 4, or 2 symbols. Each slot may include 14 or 12 symbols, depending on whether the cyclic prefix (CP) is normal or extended. For normal CP, each slot may include 14 symbols, and for extended CP, each slot may include 12 symbols. The symbols on DL may be CP orthogonal frequency division multiplexing (OFDM) (CP-OFDM) symbols. The symbols on UL may be CP-OFDM symbols (for high throughput scenarios) or discrete Fourier transform (DFT) spread OFDM (DFT-s-OFDM) symbols (for power limited scenarios; limited to a single stream transmission). The number of slots within a subframe is based on the CP and the numerology. The numerology defines the subcarrier spacing (SCS) (see Table 1). The symbol length/duration may scale with 1/SCS.

TABLE 1
Numerology, SCS, and CP

| | SCS | |
|---|---|---|
| μ | Δf = 2^{μ} · 15 [kHz] | Cyclic prefix |
| 0 | 15 | Normal |
| 1 | 30 | Normal |
| 2 | 60 | Normal, |
| | | Extended |
| 3 | 120 | Normal |
| 4 | 240 | Normal |
| 5 | 480 | Normal |
| 6 | 960 | Normal |

For normal CP (14 symbols/slot), different numerologies μ0 to 4 allow for 1, 2, 4, 8, and 16 slots, respectively, per subframe. For extended CP, the numerology 2 allows for 4 slots per subframe. Accordingly, for normal CP and numerology μ, there are 14 symbols/slot and 2^{μ} slots/subframe. The subcarrier spacing may be equal to 2^{μ}*15 kHz, where μ is the numerology 0 to 4. As such, the numerology μ=0 has a subcarrier spacing of 15 kHz and the numerology μ=4 has a subcarrier spacing of 240 kHz. The symbol length/duration is inversely related to the subcarrier spacing. FIGS. 2A-2D provide an example of normal CP with 14 symbols per slot and numerology μ=2 with 4 slots per subframe. The slot duration is 0.25 ms, the subcarrier spacing is 60 kHz, and the symbol duration is approximately 16.67 μs. Within a set of frames, there may be one or more different bandwidth parts (BWPs) (see FIG. 2B) that are frequency division multiplexed. Each BWP may have a particular numerology and CP (normal or extended).

A resource grid may be used to represent the frame structure. Each time slot includes a resource block (RB) (also referred to as physical RBs (PRBs)) that extends 12 consecutive subcarriers. The resource grid is divided into multiple resource elements (REs). The number of bits carried by each RE depends on the modulation scheme.

As illustrated in FIG. 2A, some of the REs carry reference (pilot) signals (RS) for the UE. The RS may include demodulation RS (DM-RS) (indicated as R for one particular configuration, but other DM-RS configurations are possible) and channel state information reference signals (CSI-RS) for channel estimation at the UE. The RS may also include beam measurement RS (BRS), beam refinement RS (BRRS), and phase tracking RS (PT-RS).

FIG. 2B illustrates an example of various DL channels within a subframe of a frame. The physical downlink control channel (PDCCH) carries DCI within one or more control channel elements (CCEs) (e.g., 1, 2, 4, 8, or 16 CCEs), each CCE including six RE groups (REGs), each REG including 12 consecutive REs in an OFDM symbol of an RB. A PDCCH within one BWP may be referred to as a control resource set (CORESET). A UE is configured to monitor PDCCH candidates in a PDCCH search space (e.g., common search space, UE-specific search space) during PDCCH monitoring occasions on the CORESET, where the PDCCH candidates have different DCI formats and different aggregation levels. Additional BWPs may be located at greater and/or lower frequencies across the channel bandwidth. A primary synchronization signal (PSS) may be within symbol 2 of particular subframes of a frame. The PSS is used by a UE 104 to determine subframe/symbol timing and a physical layer identity. A secondary synchronization signal (SSS) may be within symbol 4 of particular subframes of a frame. The SSS is used by a UE to determine a physical layer cell identity group number and radio frame timing. Based on the physical layer identity and the physical layer cell identity group number, the UE can determine a physical cell identifier (PCI). Based on the PCI, the UE can determine the locations of the DM-RS. The physical broadcast channel (PBCH), which carries a master information block (MIB), may be logically grouped with the PSS and SSS to form a synchronization signal (SS)/PBCH block (also referred to as SS block (SSB)). The MIB provides a number of RBs in the system bandwidth and a system frame number (SFN). The physical downlink shared channel (PDSCH) carries user data, broadcast system information not transmitted through the PBCH such as system information blocks (SIBs), and paging messages.

As illustrated in FIG. 2C, some of the REs carry DM-RS (indicated as R for one particular configuration, but other DM-RS configurations are possible) for channel estimation at the base station. The UE may transmit DM-RS for the physical uplink control channel (PUCCH) and DM-RS for the physical uplink shared channel (PUSCH). The PUSCH DM-RS may be transmitted in the first one or two symbols of the PUSCH. The PUCCH DM-RS may be transmitted in different configurations depending on whether short or long PUCCHs are transmitted and depending on the particular PUCCH format used. The UE may transmit sounding reference signals (SRS). The SRS may be transmitted in the last symbol of a subframe. The SRS may have a comb structure, and a UE may transmit SRS on one of the combs. The SRS may be used by a base station for channel quality estimation to enable frequency-dependent scheduling on the UL.

FIG. 2D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and hybrid automatic repeat request (HARQ) acknowledgment (ACK) (HARQ-ACK) feedback (i.e., one or more HARQ ACK bits indicating one or more ACK and/or negative ACK (NACK)). The PUSCH carries data, and may additionally be used to carry a buffer status report (BSR), a power headroom report (PHR), and/or UCI.

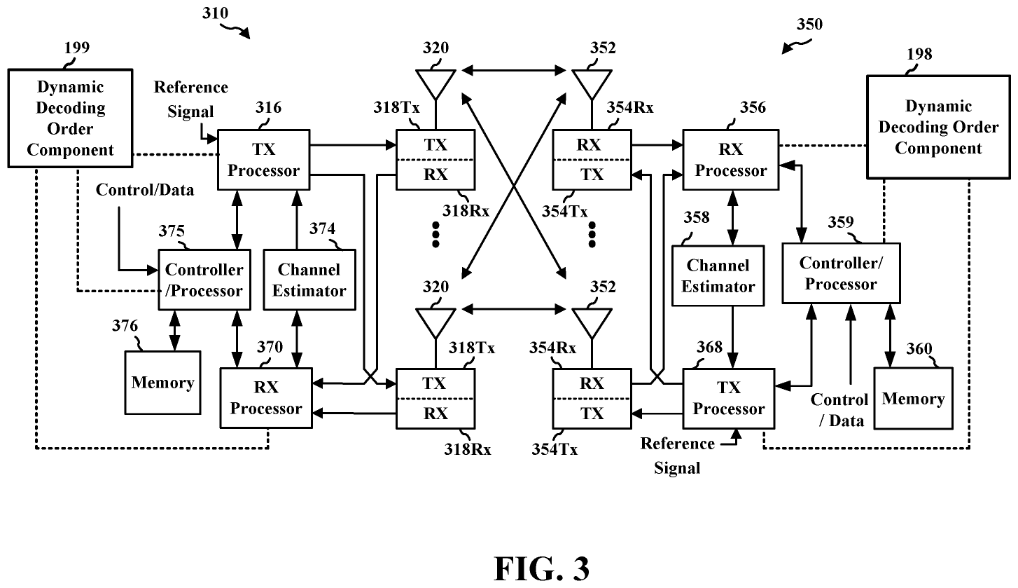

FIG. 3 is a block diagram of a base station 310 in communication with a UE 350 in an access network. In the DL, Internet protocol (IP) packets may be provided to a controller/processor 375. The controller/processor 375 implements layer 3 and layer 2 functionality. Layer 3 includes a radio resource control (RRC) layer, and layer 2 includes a service data adaptation protocol (SDAP) layer, a packet data convergence protocol (PDCP) layer, a radio link control (RLC) layer, and a medium access control (MAC) layer. The controller/processor 375 provides RRC layer functionality associated with broadcasting of system information (e.g., MIB, SIBs), RRC connection control (e.g., RRC connection paging, RRC connection establishment, RRC connection modification, and RRC connection release), inter radio access technology (RAT) mobility, and measurement configuration for UE measurement reporting; PDCP layer functionality associated with header compression/decompression, security (ciphering, deciphering, integrity protection, integrity verification), and handover support functions; RLC layer functionality associated with the transfer of upper layer packet data units (PDUs), error correction through ARQ, concatenation, segmentation, and reassembly of RLC service data units (SDUs), re-segmentation of RLC data PDUs, and reordering of RLC data PDUs; and MAC layer functionality associated with mapping between logical channels and transport channels, multiplexing of MAC SDUs onto transport blocks (TBs), demultiplexing of MAC SDUs from TBs, scheduling information reporting, error correction through HARQ, priority handling, and logical channel prioritization.

The transmit (TX) processor 316 and the receive (RX) processor 370 implement layer 1 functionality associated with various signal processing functions. Layer 1, which includes a physical (PHY) layer, may include error detection on the transport channels, forward error correction (FEC) coding/decoding of the transport channels, interleaving, rate matching, mapping onto physical channels, modulation/demodulation of physical channels, and MIMO antenna processing. The TX processor 316 handles mapping to signal constellations based on various modulation schemes (e.g., binary phase-shift keying (BPSK), quadrature phase-shift keying (QPSK), M-phase-shift keying (M-PSK), M-quadrature amplitude modulation (M-QAM)). The coded and modulated symbols may then be split into parallel streams. Each stream may then be mapped to an OFDM subcarrier, multiplexed with a reference signal (e.g., pilot) in the time and/or frequency domain, and then combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 374 may be used to determine the coding and modulation scheme, as well as for spatial processing. The channel estimate may be derived from a reference signal and/or channel condition feedback transmitted by the UE 350. Each spatial stream may then be provided to a different antenna 320 via a separate transmitter 318Tx. Each transmitter 318Tx may modulate a radio frequency (RF) carrier with a respective spatial stream for transmission.

At the UE 350, each receiver 354Rx receives a signal through its respective antenna 352. Each receiver 354Rx recovers information modulated onto an RF carrier and provides the information to the receive (RX) processor 356. The TX processor 368 and the RX processor 356 implement layer 1 functionality associated with various signal processing functions. The RX processor 356 may perform spatial processing on the information to recover any spatial streams destined for the UE 350. If multiple spatial streams are destined for the UE 350, they may be combined by the RX processor 356 into a single OFDM symbol stream. The RX processor 356 then converts the OFDM symbol stream from the time-domain to the frequency domain using a Fast Fourier Transform (FFT). The frequency domain signal includes a separate OFDM symbol stream for each subcarrier of the OFDM signal. The symbols on each subcarrier, and the reference signal, are recovered and demodulated by determining the most likely signal constellation points transmitted by the base station 310. These soft decisions may be based on channel estimates computed by the channel estimator 358. The soft decisions are then decoded and deinterleaved to recover the data and control signals that were originally transmitted by the base station 310 on the physical channel. The data and control signals are then provided to the controller/processor 359, which implements layer 3 and layer 2 functionality.

The controller/processor 359 can be associated with at least one memory 360 that stores program codes and data. The at least one memory 360 may be referred to as a computer-readable medium. In the UL, the controller/processor 359 provides demultiplexing between transport and logical channels, packet reassembly, deciphering, header decompression, and control signal processing to recover IP packets. The controller/processor 359 is also responsible for error detection using an ACK and/or NACK protocol to support HARQ operations.

Similar to the functionality described in connection with the DL transmission by the base station 310, the controller/processor 359 provides RRC layer functionality associated with system information (e.g., MIB, SIBs) acquisition, RRC connections, and measurement reporting; PDCP layer functionality associated with header compression/decompression, and security (ciphering, deciphering, integrity protection, integrity verification); RLC layer functionality associated with the transfer of upper layer PDUs, error correction through ARQ, concatenation, segmentation, and reassembly of RLC SDUs, re-segmentation of RLC data PDUs, and reordering of RLC data PDUs; and MAC layer functionality associated with mapping between logical channels and transport channels, multiplexing of MAC SDUs onto TBs, demultiplexing of MAC SDUs from TBs, scheduling information reporting, error correction through HARQ, priority handling, and logical channel prioritization.

Channel estimates derived by a channel estimator 358 from a reference signal or feedback transmitted by the base station 310 may be used by the TX processor 368 to select the appropriate coding and modulation schemes, and to facilitate spatial processing. The spatial streams generated by the TX processor 368 may be provided to different antenna 352 via separate transmitters 354Tx. Each transmitter 354Tx may modulate an RF carrier with a respective spatial stream for transmission.

The UL transmission is processed at the base station 310 in a manner similar to that described in connection with the receiver function at the UE 350. Each receiver 318Rx receives a signal through its respective antenna 320. Each receiver 318Rx recovers information modulated onto an RF carrier and provides the information to a RX processor 370.

The controller/processor 375 can be associated with at least one memory 376 that stores program codes and data. The at least one memory 376 may be referred to as a computer-readable medium. In the UL, the controller/processor 375 provides demultiplexing between transport and logical channels, packet reassembly, deciphering, header decompression, control signal processing to recover IP packets. The controller/processor 375 is also responsible for error detection using an ACK and/or NACK protocol to support HARQ operations.

At least one of the TX processor 368, the RX processor 356, and the controller/processor 359 may be configured to perform aspects in connection with the component 198 of FIG. 1.

At least one of the TX processor 316, the RX processor 370, and the controller/processor 375 may be configured to perform aspects in connection with the component 199 of FIG. 1.

Communications between network nodes (e.g., base stations, gNBs, etc.) and UEs, or transmitter network devices and receiver network devices, generally, may utilize polar codes for channel polarization of communication payloads. A polar code is based on the phenomenon of channel polarization, where communication channels, after applying the polar transform (e.g., with an Arikan kernel), may converge to either of a useless or a noiseless channel. Polar code design may include determining which bit locations are allocated to send information bits and which bit locations to send frozen bits. SC decoding (e.g., with a fixed decoding order) and SCL decoding are common decoding algorithms that may be used for polar code implementations.

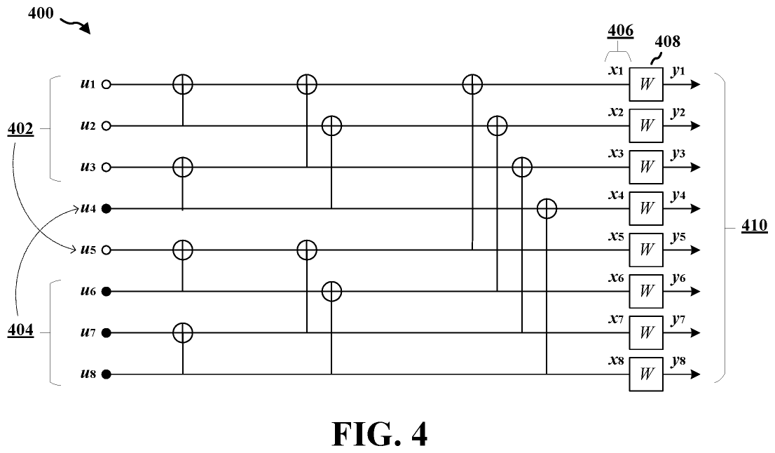

FIG. 4 is a diagram 400 illustrating an example of a basic polar coding. Diagram 400 shows a representation of fixed-order polar coding based on a generator matrix that may be applied to a set of bits for polar coding by a first device. The set of bits may include a subset of frozen bits 402 (e.g., u₁, u₂, u₃, u₅) and a subset of information bits 404 (e.g., u₄, u₆, u₇, u₈). The subset of frozen bits 402 and the subset of information bits 404 may be processed according to the generator matrix based on a Hamming weight (e.g., a number of times each bit of the set of bits is combined with another bit of the set of bits. For example, a Hamming weight of 3 may be applied to the bit u₁, a Hamming weight of 2 may be applied to bits u₂, u₃, and u₅, a Hamming weight of 1 may be applied to bits u₄, u₆, and u₇, and a Hamming weight of 0 (zero) may be applied to bit u₈. The application of the generator matrix may be a weighted set of bits 406 {x₁, x₂, x₃, x₄, x₅, x₆, x₇, x₈} to which a polar transform 408 (W) is applied to generate an output of a set of encoded bits 410 {y₁, y₂, y₃, y₄, y₅, y₆, y₇, y₈}. The set of encoded bits 410 may be transmitted/provided to a second device in accordance with the polar coding illustrated.

However, fixed decoding order solutions are limited to bit-by-bit sequential decoding of fixed-position bits in a block to be polar encoded for a communication payload. Such fixed order decoding lacks mechanisms to improve error probabilities for bits in communication payloads. Additionally, fixed order decoding may have issues with optimizations and enhancements such as decoder-specific optimizations through code construction for faster/more efficient polarization, extensibility to other types of decoding (e.g., list decoding), the implementation of CRC, scaling to blocks with larger numbers of bits for communication payloads, and avoidance of disproportionate decoding steps for increasing numbers of bits encoded.

Aspects described herein for polar coding with efficient polarization and dynamic decoding orders provide solutions to such issues. Aspects herein provide techniques for polar decoding and construction. The new decoding algorithm was motivated from permutation-based decoding, which avoids some major challenges associated with a permutation decoder while maintaining the primary benefit. A new polar sequence design approach is proposed for the decoder to obtain optimal performance. Accordingly, aspects described herein for polar coding with efficient polarization and dynamic decoding orders provide solutions to such issues. Aspects enable a polar code to be decoded with a different decoding order (that preserves the polar code, e.g., via automorphism ensemble decoding), and by which the decoding results may depend on the decoding order by utilizing permutation-based polar decoding using automorphisms. Aspects enable a decoder to decode the same received signal in accordance with different decoding orders (e.g., permutations) and more efficiently identify the best result from specific subsets of these permutations by utilizing permutation-based polar decoding using automorphisms. Aspects enable a polar decoder to perform a faster polarization than conventional polar codes by utilizing automorphism in polar code construction and decoder characteristics. Accordingly, aspects improve error probabilities for bits in communication payloads and provide for optimizations and enhancements such as decoder-specific optimizations through code construction for faster/more efficient polarization, extensibility to other types of decoding (e.g., list decoding), the implementation of CRC, scaling to blocks with larger numbers of bits for communication payloads, and avoidance of disproportionate decoding steps for increasing numbers of bits encoded.

A sequential decoder may be configured to decode bit-by-bit in association with bit probabilities, e.g., p(u₁)p(u₂|u₁)p(u₃|u₂,u₁) . . . , and for a received frame, an ML probability of error may be fixed: p(u₁, u₂, u₃, . . . ). In accordance with aspects, in the earlier stages of polar decoding, frozen bits may be associated with bits having a greater/worse probability of error than information bits. In this way, “more of the errors” associated with bits of a communication payload may be corrected by using known bits. In other words, in a polar decoder, the order of decoding may be dynamically changed in accordance with properties of the polar code. Aspects herein for polar coding with efficient polarization and dynamic decoding order utilize such a dynamic decoding order to provide a larger probability of error for the frozen bit locations (e.g., larger path metric for earlier bits), which may lead to fewer errors for the remaining bits, such as the information bits. Aspects further utilize permutations/automorphisms associated with the polar codes described herein to dynamically change the decoding order and give priority to bits having a greater/worse probability of error.

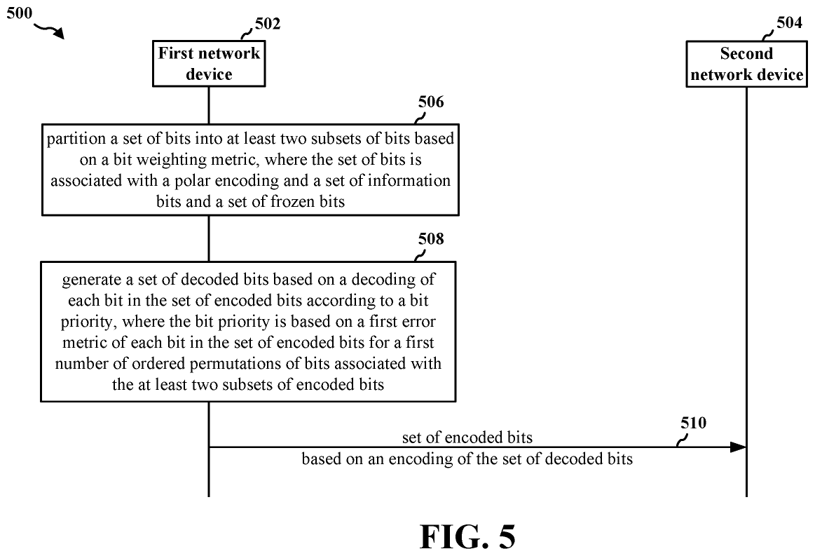

Accordingly, a decoding algorithm implemented by a polar decoder may be configured to enable such benefits for polar coding with efficient polarization and dynamic decoding order. For example, a decoder according to aspects herein may configured to partition a set of bits into groups, e.g., subsets, with the same bit weighting metric (e.g., a Hamming weight) as in the generator matrix—that is, the set of bits may be decoded at a specific bit location using permutations. The decoder may be configured to determine/identify the permutations for each bit in the specific group, considering all previous selected and decoded bits are removed from that group, and to select the bit in the group that is most likely to be in error (e.g., having a smallest log likelihood ratio (LLR) magnitude/largest path metric), decode that bit, and then remove the selected bit from its group. In such context, FIG. 5 is described below.

FIG. 5 is a call flow diagram 500 for wireless communications, in various aspects. Call flow diagram 500 illustrates polar coding with efficient polarization and dynamic decoding order for a first network device 502 (e.g., a UE, a base station such as a gNB or other type of base station, etc., as shown and described herein), by way of example that communicates with a second network device 504 (e.g., another UE, another base station, etc., as shown and described herein), by way of example. Aspects described for base stations, and for network nodes/entities herein, generally, may be performed in aggregated form and/or by one or more components in disaggregated form. Additionally, or alternatively, the aspects may be performed by a UE autonomously, in addition to, and/or in lieu of, operations of a base station.

In the illustrated aspect, the first network device 502 may be configured to partition (at 506) a set of bits into at least two subsets of bits based on a bit weighting metric, where the set of bits is associated with a polar encoding and a set of information bits and a set of frozen bits. The set of bits may be a block or other set of bits associated with a communication payload in accordance with polar coding with efficient polarization and dynamic decoding order. In aspects, the set of bits may include a total number of bits, and the at least two subsets of bits may include a second number of subsets that is one more than a base-two logarithm value (e.g., the number of subsets equals n+1, or equals 1+log₂ N, where N is the total number of bits or block length and n=log₂ N). In aspects, the bit weighting metric may be a Hamming weight associated with a generator matrix for the polar code. Similarly, each bit included in a respective subset of the at least two subsets of bits may have a same Hamming weight (e.g., {n, n−1, . . . , 0}).

The first network device 502 may be configured to generate (at 508) a set of decoded bits based on a decoding of each bit in the set of bits according to a bit priority, where the bit priority is based on a first error metric of each bit in the set of bits for a first number of ordered permutations of bits associated with the at least two subsets of bits. The first error metric may be a smallest log likelihood ratio and/or a largest path metric, and to generate (at 508) the set of decoded bits, the first network device 502 may be configured to identify each of the first number of ordered permutations of bits associated with the at least two subsets of bits.

In aspects, to generate (at 508) the set of decoded bits, first network device 502 may be configured to: (1) identify a bit to be decoded from the set of bits based on: a match of the bit to be decoded between one of the first number of ordered permutations of bits and the at least two subsets of bits, and the bit priority, (2) generate a decoded bit by decoding (e.g., being configured to decode) the bit to be decoded, and (3) remove the decoded bit from the at least two subsets of bits. In such aspects, the first network device 502 may be configured to repeat (1) to (3) for each bit in the set of bits. That is, the first network device 502 may be configured to iterate over the set of bits and perform the identification, the generation, and the removal for each bit in the set of bits for subsequent iterations.

In aspects, to generate (at 508) the set of decoded bits, first network device 502 may be configured to identify the set of information bits based on a second error metric in each bit of the set of decoded bits. In such aspects, the second error metric may be a reliability metric associated with bit locations of the set of decoded bits. Additionally, in such aspects, a code rate for the decoding of each bit in the set of bits may be based on a ratio of a number of information bits in the set of information bits to a total number of bits in the set of bits. To identify the set of information bits based on the second error metric in each bit of the set of decoded bits, the first network device 502 may be configured to calculate a second number of bits for the set of frozen bits as a difference between the total number of bits in the set of bits and the number of information bits. Accordingly, the first network device 502 may be configured to identify the set of frozen bits as the second number of bits that includes a lower reliability metric associated with the bit locations of the set of decoded bits than remaining bits of the set of bits, and to identify the set of information bits as the remaining bits of the set of bits. In some aspects, the decoding of each bit in the set of bits by the first network device 502 may be associated with a binary erasure channel (BEC), an additive white Gaussian noise (AWGN) channel, a binary symmetric channel (BSC), and/or the like.

The first network device 502 may be configured to transmit, for the second network device 504, a set of encoded bits 510 that are based on an encoding of the set of decoded bits. For example, when the first network device 502 is a UE, such a UE may be configured to transmit the set of encoded bits 510 that are based on the encoding of the set of decoded bits to a base station. As another example, when the first network device 502 is a base station, such a base station may be configured to transmit the set of encoded bits 510 that are based on the encoding of the set of decoded bits to a UE. In aspects, the first network device 502 may be configured to output an indication of at least one of the set of generated decoded bits or the set of encoded bits. In such aspects, the first network device 502 may be configured to transmit the indication of the set of generated decoded bits (e.g., to the second network device 504) and/or to store the indication of at least one of the set of generated decoded bits or the set of encoded bits. In such aspects, storing the indication or the set of encoded bits may include storing in at least one memory of the first network device 502.

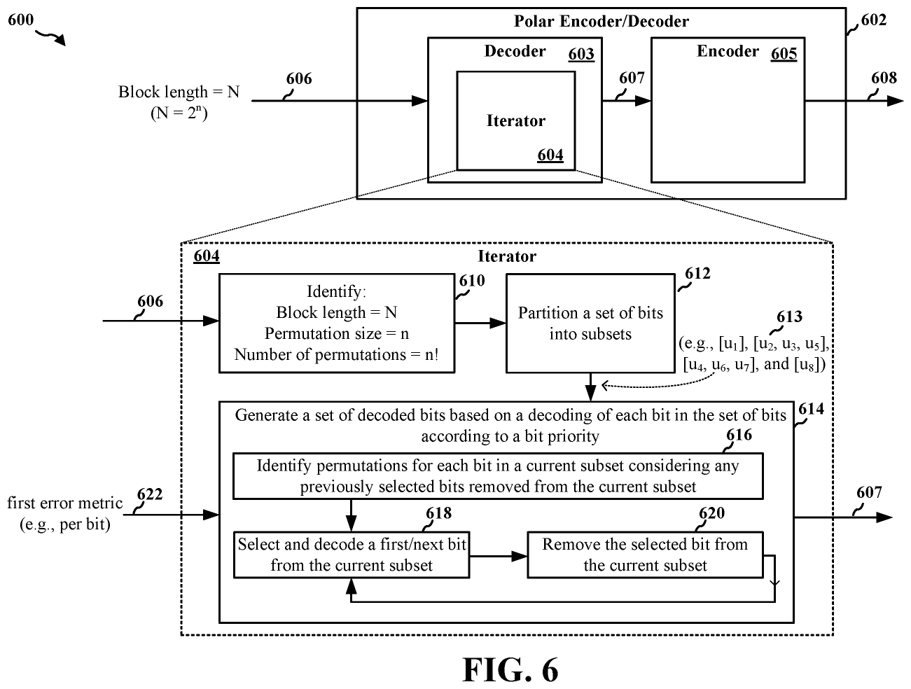

FIG. 6 is a diagram 600 illustrating an example of polar coding with efficient polarization and dynamic decoding order, in various aspects. Diagram 600 may be an aspect of the call flow diagram 500 in FIG. 5. Diagram 600 shows a polar encoder/decoder 602, which may include (or comprise) a decoder 603 portion and an encoder 605 portion of the first network device 502 in FIG. 5. As shown, the decoder 603 may include an iterator 604 configured for polar coding with efficient polarization and dynamic decoding order.

The decoder 603 may be configured to receive/obtain a set of bits 606. In aspects, the set of bits 606 may be a block or other set of bits associated with a communication payload in accordance with polar coding with efficient polarization and dynamic decoding order, and may have a length ‘N’, where N=2ⁿ and the permutation size and the number of permutations are calculated based on ‘n’. In aspects, the decoder 603 and/or the iterator 604 may be configured to identify (at 610) the block length ‘N’, the permutation size ‘n’, and the number of permutations ‘n!’. The decoder 603 and/or the iterator 604 may be configured to partition (at 612) the set of bits 606 into at least two subsets of bits 613 based on a bit weighting metric, where the set of bits 606 is associated with a polar encoding and a set of information bits and a set of frozen bits. The decoder 603 and/or the iterator 604 may also be configured to generate (at 614) a set of decoded bits 607 based on a decoding of each bit in the set of bits 606 according to a bit priority, where the bit priority is based on a first error metric 622 (e.g., a smallest log likelihood ratio and/or a largest path metric) of each bit in the set of bits 606 for a first number of ordered permutations of bits associated with the at least two subsets of bits 613. The encoder 605 may be configured to encode the set of decoded bits 607 and output a set of encoded bits 608. In the context of the first network device 502 in the call flow diagram 500, described above, and the diagram 600, a non-limiting example of polar coding with efficient polarization and dynamic decoding order is now provided, as shown in diagram 600.

In the example, a block length of N=8 is identified (at 610) (although other lengths are contemplated for aspects herein), where n=3 and N=2ⁿ. The number of ordered permutations may be identified (at 610) as the factorial of n (e.g., n!), in aspects, and in this example, n!=3!=6. The block, or the set of bits 606, may be represented in this example as [1, 2, 3, 4, 5, 6, 7, 8], and the permutations may be identified (at 616) as: [3, 2, 1], [3, 1, 2], [2, 3, 1], [2, 1, 3], [1, 3, 2], and [1, 2, 3], which may respectively correspond to the following representations of the set of bits: [1, 5, 3, 7, 2, 6, 4, 8], [1, 5, 2, 6, 3, 7, 4, 8], [1, 3, 5, 7, 2, 4, 6, 8], [1, 2, 5, 6, 3, 4, 7, 8], [1, 3, 2, 4, 5, 7, 6, 8], and [1, 2, 3, 4, 5, 6, 7, 8].

For purposes of illustration and conceptualization of the example, the bits of the set of bits 606 that are in partitioned (at 612) by the first network device 502 into the same groups (e.g., the same subset of two or more subsets 613) may be based on associations in the generator matrix for the polar code. That is, it may be conceptualized as bits of the set of bits 606 that are in partitioned (at 612) into the same groups/subsets 613 may have a same monomial degree in the context of Reed-Muller (RM) codes: bit positions [1], [2, 3, 5], [4, 6, 7], [8] (e.g., as shown by way of example in FIG. 4, described above for [u₁], [u₂, u₃, u₅], [u₄, u₆, u₇], and [u₈] for a length of N=8).

For the instant example, the permutations [3, 1, 2], [2, 3, 1], and [1, 2, 3], which may respectively correspond to the representations of the set of bits: [1, 5, 2, 6, 3, 7, 4, 8], [1, 3, 5, 7, 2, 4, 6, 8], and [1, 2, 3, 4, 5, 6, 7, 8] may be utilized. The first bit is in the group/subset [1]. That is, the first bit in the first position may be a subset by itself. The first network device 502 may be configured to select (at 618) bit 1 (e.g., being the sole bit, by default) and decode it (at 618), and/or remove it (at 620) from further consideration.

The second bit is in the group/subset [2, 3, 5], and utilizing the permutations (e.g., identified at 616) noted above, the first network device 502 may be configured to select the corresponding bit with the greater/worse probability of error (e.g., bit 3 in this example) and decode it (at 618), and/or remove it (at 620) from the group/subset. Thus, the new/updated group/subset may be [2, 5], and possible permutations (e.g., identified at 616) for the next bit may be [1, 3, 5, 7, 2, 4, 6, 8], [1, 3, 2, 4, 5, 7, 6, 8]. The third bit is in the group/subset [2, 5], and utilizing the possible permutations (e.g., identified at 616), the first network device 502 may be configured to select the corresponding bit with the greater/worse probability of error (e.g., bit 5 in this example) and decode it (at 618), and/or remove it (at 620) from the group/subset. Thus, the new/updated group/subset may be [2], and possible permutations (e.g., identified at 616) for the next bit may be [1, 3, 5, 7, 2, 4, 6, 8], [1, 5, 3, 7, 2, 6, 4, 8]. The fourth bit is in the group/subset [4, 6, 7] but just bit 7 is possible based on the available bits in the permutations, and utilizing the possible permutations (e.g., identified at 616), the first network device 502 may be configured to select the corresponding bit with the greater/worse probability of error (e.g., bit 7 in this example, by default) and decode it (at 618), and/or remove it (at 620) from the group/subset. Thus, the new/updated group/subset may be [4, 6], and possible permutations (e.g., identified at 616) for the next bit may be [1, 3, 5, 7, 2, 4, 6, 8], [1, 5, 3, 7, 2, 6, 4, 8].

The fifth bit is in the group/subset [2]. Utilizing the possible permutations (e.g., identified at 616), the first network device 502 may be configured to select the corresponding bit with the greater/worse probability of error (e.g., bit 2 in this example, by default) and decode it (at 618), and/or remove it (at 620) from the group/subset. Thus, the new/updated group/subset may be empty (‘[ ]’), and possible permutations (e.g., identified at 616) for the next bit may be [1, 3, 5, 7, 2, 4, 6, 8], [1, 5, 3, 7, 2, 6, 4, 8]. The sixth bit is in the group/subset [4, 6], and utilizing possible permutations (e.g., identified at 616), the first network device 502 may be configured to select the corresponding bit with the greater/worse probability of error (e.g., bit 6 in this example) and decode it (at 618), and/or remove it (at 620) from the group/subset. Thus, the new/updated group/subset may be [4], and possible permutations (e.g., identified at 616) for the next bit may be [1, 5, 3, 7, 2, 6, 4, 8]. The seventh bit is in the group/subset [4], and utilizing the possible permutations (e.g., identified at 616), the first network device 502 may be configured to select the corresponding bit with the greater/worse probability of error (e.g., bit 4 in this example, by default) and decode it (at 618), and/or remove it (at 620) from the group/subset. Thus, the new/updated group/subset may be empty (‘[ ]’), and possible permutations (e.g., identified at 616) for the next bit may be [1, 5, 3, 7, 2, 6, 4, 8]. The eighth bit is in the group/subset [8], as it the sole bit remaining. The network device 502 may be configured to select the corresponding bit with the greater/worse probability of error (e.g., bit 8 in this example, by default) and decode it (at 618), and/or remove it (at 620) from the group/subset.

Accordingly, a set of decoded bits 607 may be generated (e.g., at 508) based on a decoding (e.g., at 618) of each bit in the set of bits 606 according to a bit priority, where the bit priority is based on the first error metric 622 of each bit in the set of bits 606 for a first number of ordered permutations (e.g., identified at 616) of bits associated with the at least two subsets of bits 613 (e.g., partitioned at 610). Subsequently, the encoder 605 may be configured to output the set of encoded bits 608 based on the set of decoded bits 607.

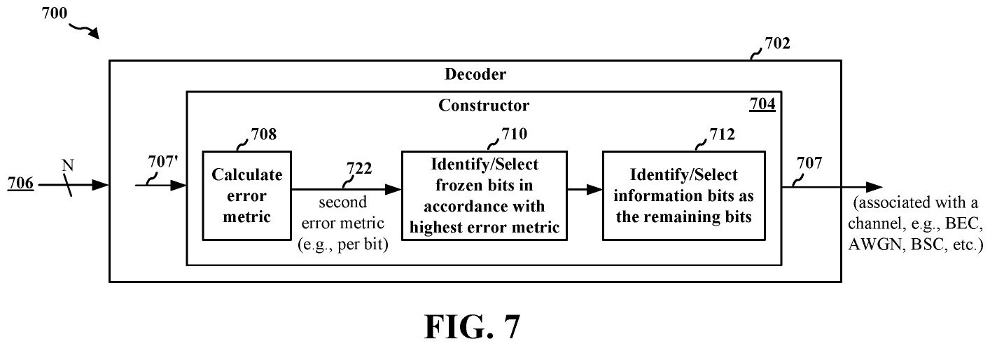

FIG. 7 is a diagram 700 illustrating an example of polar coding with efficient polarization and dynamic decoding order, in various aspects. Diagram 600 may be an aspect of the call flow diagram 500 in FIG. 5 and/or the diagram 600 in FIG. 6. Diagram 700 shows an example of polar code construction, in such aspects, for a decoder 702, e.g., a polar decoder of the first network device 502 in FIG. 5, that may include a constructor 704 for polar coding with efficient polarization and dynamic decoding order. The decoder 702 may be an aspect of the decoder 603 in FIG. 6, and may be configured to receive a set of bits 706 of length N (e.g., as similarly described in FIG. 6 for the set of bits 606).

In aspects, the constructor 704 may be configured to generate (in addition to/in lieu of/as part of an iterator, as described herein (e.g., the iterator 604 in FIG. 6)) a set of decoded bits 707 based on the decoding of each bit in the set of bits 706 according to the bit priority. In such aspects, the constructor 704 may be configured to identify (at 712) a set of information bits based on a second error metric 722 in each of bits 707′ of the set of decoded bits 707. The second error metric may be a reliability metric (e.g., a bit error rate (BER) and/or the like, in aspects) for a probability of error that may be associated with bit locations of the bits 707′ of set of decoded bits 707. In such aspects, a code rate for the decoding of each bit in the set of bits 706 to generate the set of decoded bits 707 may be based on a ratio of a number of information bits in a set of information bits to a total number of bits in the set of bits. In aspects, a Monte Carlo simulation may be used to determine/calculate (at 708) the reliability metric

$$R = \frac{K}{N} ,$$

(e.g., BER). In one example aspect, depending on the code rate R, where the N−K least reliable of the bits 707′ of the set of decoded bits 707 (e.g., with a lowest reliability metric/with a highest BER) are selected/identified (at 710) as frozen bits, and the remaining K bits may be selected/identified (at 712) as information bits for the set of decoded bits 707, which may thus be reordered/sorted accordingly for polar encoding. That is, for some aspects, to select/identify (at 712) the set of information bits based on the second error metric 722 in each bit 707′ of the set of decoded bits 707, the constructor 704 may be configured to calculate (at 708) a second number of bits for the set of frozen bits as a difference between the total number of bits (e.g., N) in the set of bits 706 and the number of information bits, select/identify (at 710) the set of frozen bits as the second number of bits that includes a lower reliability metric (e.g., for the second error metric 722) associated with the bit locations of bits 707′ of the set of decoded bits 707 than remaining bits of the set of bits 706, and select/identify (at 712) the set of information bits as the remaining bits (e.g., of the bits 707′) of the set of bits 706 that have been decoded to the set of decoded bits 707. Aspects also provide for selecting/identifying (at 712) as the information bits the K most reliable of the bits 707′ of the set of decoded bits 707 (e.g., with a highest reliability metric/with a lowest BER), and the remaining N−K bits may be selected/identified (at 712) as information bits for the set of decoded bits 707. In some aspects, the decoding of each bit in the set of bits 706 to generate the set of decoded bits 707 may be associated with at least one of a binary erasure channel (BEC), an additive white Gaussian noise (AWGN) channel, or a binary symmetric channel (BSC).

Accordingly, the aspects herein for polar coding with efficient polarization and dynamic decoding order provides a better scaling exponent (e.g., a faster polarization) than the standard polar code. The construction for the illustrated example in diagram 700, aspects may also provide for a different bit-channel reliability order than the standard polar code, e.g., for n≥4. For instance, assuming n=4, the standard polar code has a universal bit-channel reliability order (from most reliable to least reliable) of:
[16, 15, 14, 12, 8, 13, 11, 10, 7, 6, 4, 9, 5, 3, 2, 1].

In contrast, aspects herein for polar coding with efficient polarization and dynamic decoding order provide a different reliability order (from most reliable to least reliable) of:
[16, 15, 14, 12, 13, 8, 11, 7, 10, 4, 6, 9, 5, 3, 2, 1].

That is, several bit locations may have a different reliability order compared to the standard polar code when n≥4. For n<4, the legacy polar code and the aspects herein may result in the same reliability order.

In another illustrative example for the construction shown in diagram 700, e.g., assuming that n=7 and a BEC with a code rate of 0.5, the 64 most reliable bits may be the information bits. There may be different positions for the most reliable bits at [31, 46, 57, 98]. With respect to RM, there may be different reliable bits in position between the aspects herein for polar coding with efficient polarization and dynamic decoding order and the standard polar code:

[16, 24, 28, 30, 31, 40, 44, . . . , 85, 89, 98, 99, 101, 105, 113] (standard polar)
[16, 24, 28, 30, . . . , 40, 44, 46, 57, 85, 89, . . . , 99, 101, 105, 113] (dynamic order).

Accordingly, the sum of the BER of the information bits in the standard polar code for this example is 4.8591, while the sum of the information bits in the aspects for polar coding with efficient polarization and dynamic decoding is improved: 4.2983.

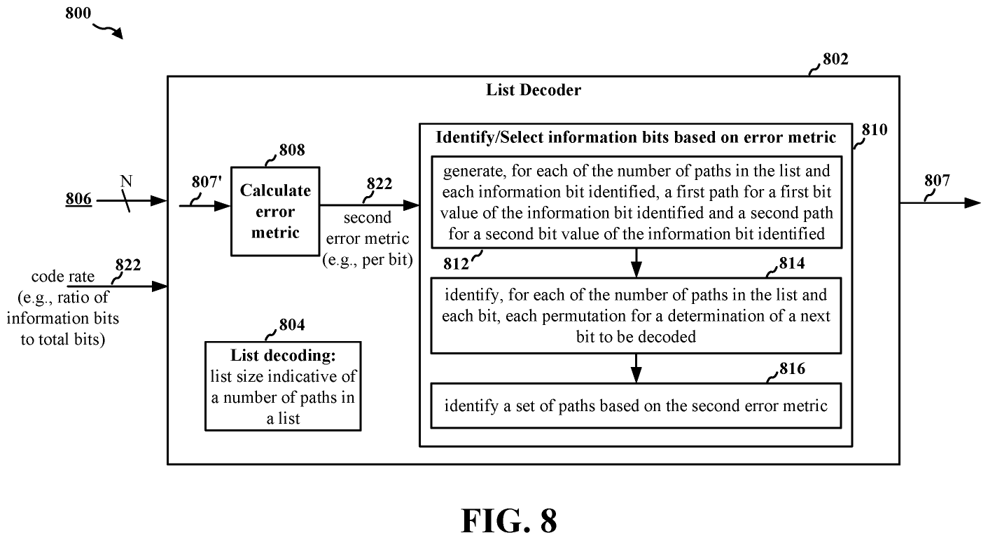

FIG. 8 is a diagram 800 illustrating an example of polar coding with efficient polarization and dynamic decoding order, in various aspects. Diagram 800 may be an aspect of the call flow diagram 500 in FIG. 5, the diagram 600 in FIG. 6, and/or the diagram 700 in FIG. 7. Diagram 800 shows the extensibility of polar coding with efficient polarization and dynamic decoding order to other decoding techniques, e.g., list decoding utilizing a list decoder 802. As described above for the diagram 700 in FIG. 7, a set of decoded bits 807 may be generated based on each bit 807′ in a set of bits 806 being decoded according to a bit priority, where the set of information bits may be identified based on a second error metric in each bit 807′ of the set of decoded bits 807.

In aspects, such as for extensions to the list decoding, a second error metric 822 may be a largest path metric, a CRC, and/or the like, and each bit 807′ in the set of bits 806 may be decoded in association with a list decoding 804 of the list decoder 802. The list decoding 804 may include a list size indicative of a number of paths in a list for the list decoding 804. In aspects, the list decoder may be configured to calculate (at 808) the second error metric 822. To identify (at 810) the set of information bits, the list decoder 802 may be configured to generate (at 812), for each of the number of paths in the list and each information bit identified, a first path for a first bit value of the information bit identified and a second path for a second bit value of the information bit identified (e.g., 0/1, or 1/0). In such aspects, the list decoder 802 may be configured to identify (at 814) or select, for each of the number of paths in the list and each bit 807′, each permutation for a determination of a next bit for bits 807′, to be decoded. In such aspects, the list decoder 802 may be configured to identify (at 816) or select a set of paths based on the second error metric 822.

In some aspects, the second error metric 822 may be the largest path metric, and the list decoder 802 may be configured to identify (at 816) the set of paths that includes a lowest largest path metric value. In some aspects, the second error metric 822 may be the CRC, and the list decoder 802 may be configured to identify (at 816) the set of paths that pass the CRC.

That is, for the list decoding 804 with a list size L in accordance with aspects for polar coding with efficient polarization and dynamic decoding order, the list decoder 802 may be configured to perform operations including at least one of: (1) for each path in the list and each information bit encountered, consider both bits 0 and 1 for the information bit and create two paths; and (2) for each path in the list and each frozen/information bit encountered, consider all permissible permutations to determine next bit to be decoded. In aspects, the combination of the above two operations (1) and (2) may create a list of candidates from which L paths are retained with the best path metric. The resulting number of candidates after path splitting and permutations may be more than 2L, however, in some aspects, to keep the number of candidates maximized at 2L (e.g., similar to legacy polar code list decoding), path splitting and permutation selection may be performed on the best p≤L paths in the list until 2L candidates are generated.

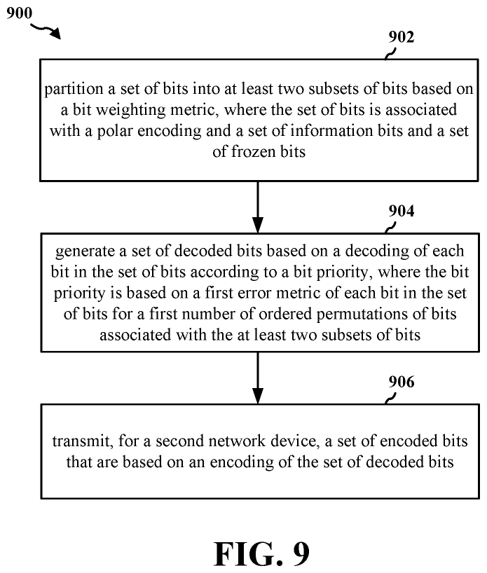

FIG. 9 is a flowchart 900 of a method of wireless communication. The method may be performed by a first network device (e.g., the first network device 502; the polar encoder/decoder 602; the decoder 702, the list decoder 802; the UE 104; the apparatus 1104; the base station 102; the network entity 1102, 1202). In some aspects, the method may include aspects described in connection with the communication flow in FIG. 5, and/or aspects described in FIGS. 4, 6, 7, 8. The method may be for dynamic frozen polar codes for probabilistic shaping. The method may improve error probabilities for bits in communication payloads and provide for optimizations and enhancements such as decoder-specific optimizations through code construction for faster/more efficient polarization, extensibility to other types of decoding (e.g., list decoding), the implementation of CRC, scaling to blocks with larger numbers of bits for communication payloads, and avoidance of disproportionate decoding steps for increasing numbers of bits encoded.

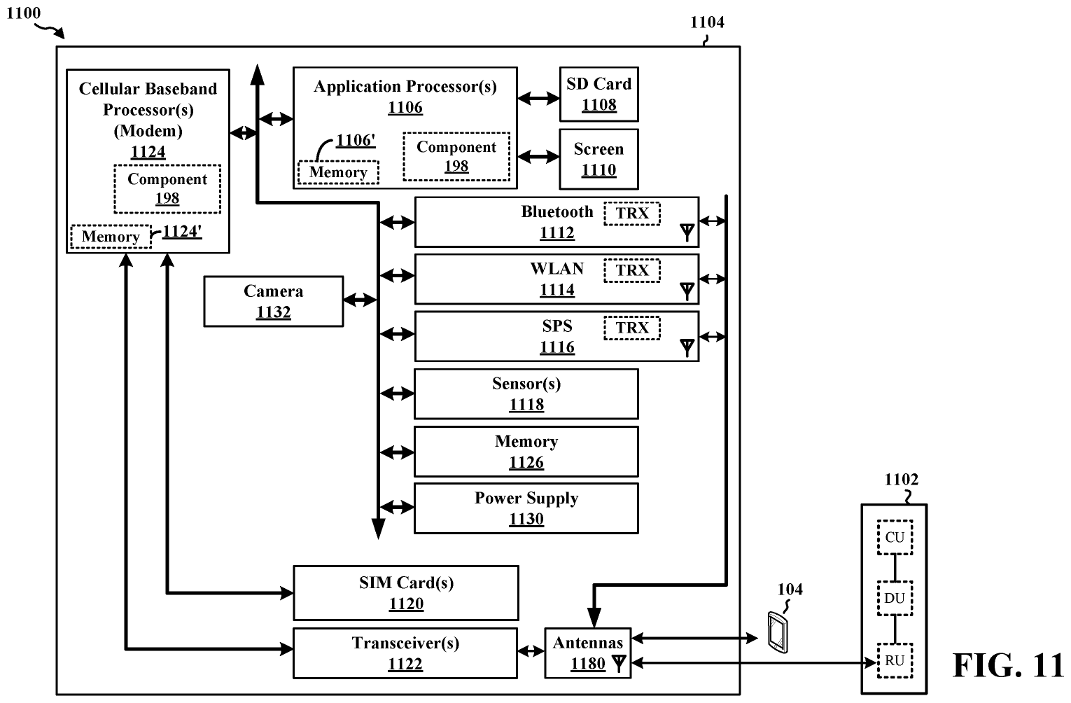

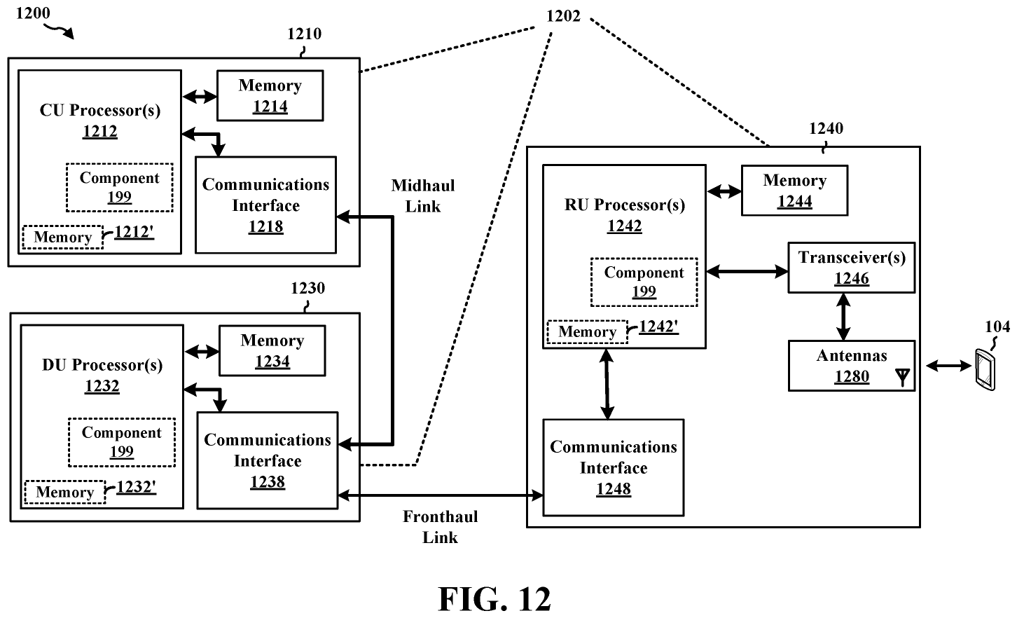

At 902, the first network device partitions a set of bits into at least two subsets of bits based on a bit weighting metric, where the set of bits is associated with a polar encoding and a set of information bits and a set of frozen bits. As an example, the partitioning may be performed by one or more of the component 198, the transceiver(s) 1122, and/or the antenna 1180 in FIG. 11, and/or may be performed by one or more of the component 199, the transceiver(s) 1246, and/or the antenna 1280 in FIG. 12. FIG. 5 illustrates, in the context of FIGS. 6, 7, 8, an example of the first network device 502 (e.g., a UE, a base station, etc.) partitioning such a set of bits into subsets.

The first network device 502 may be configured to partition (at 506) (e.g., 612 in FIG. 6) a set of bits (e.g., 606 in FIG. 6) into at least two subsets of bits (e.g., 613 in FIG. 6) based on a bit weighting metric, where the set of bits (e.g., 606 in FIG. 6) is associated with a polar encoding (e.g., 602, 605 in FIG. 6) and a set of information bits and a set of frozen bits. The set of bits (e.g., 606 in FIG. 6) may be a block or other set of bits associated with a communication payload in accordance with polar coding with efficient polarization and dynamic decoding order. In aspects, the set of bits (e.g., 606 in FIG. 6) may include a total number of bits (e.g., N in FIG. 6), and the at least two subsets of bits (e.g., 613 in FIG. 6) may include a second number of subsets that is one more than a base-two logarithm value (e.g., the number of subsets equals n+1, or equals 1+log₂ N, where N is the total number of bits or block length and n=log₂ N). In aspects, the bit weighting metric may be a Hamming weight associated with a generator matrix for the polar code. Similarly, each bit included in a respective subset of the at least two subsets of bits (e.g., 613 in FIG. 6) may have a same Hamming weight (e.g., {n, n−1, . . . , 0}).

At 904, the first network device generates a set of decoded bits based on a decoding of each bit in the set of bits according to a bit priority, where the bit priority is based on a first error metric of each bit in the set of bits for a first number of ordered permutations of bits associated with the at least two subsets of bits. As an example, the generation may be performed by one or more of the component 198, the transceiver(s) 1122, and/or the antenna 1180 in FIG. 11, and/or may be performed by one or more of the component 199, the transceiver(s) 1246, and/or the antenna 1280 in FIG. 12. FIG. 5 illustrates, in the context of FIGS. 6, 7, 8, an example of the first network device 502 generating such a set of decoded bits based on a decoding of each bit in the set of bits according to a bit priority.

The first network device 502 may be configured to generate (at 508) a set of decoded bits (e.g., 607 in FIG. 6) based on a decoding (e.g., by 603 in FIG. 6) of each bit in the set of bits (e.g., 606 in FIG. 6) according to a bit priority, where the bit priority is based on a first error metric (e.g., 622 in FIG. 6) of each bit in the set of bits (e.g., 606 in FIG. 6) for a first number of ordered permutations of bits associated with the at least two subsets of bits (e.g., 613 in FIG. 6). The first error metric (e.g., 622 in FIG. 6) may be a smallest log likelihood ratio and/or a largest path metric, and to generate (at 508) the set of decoded bits (e.g., 607 in FIG. 6), the first network device 502 may be configured to identify (e.g., at 610 in FIG. 6) each of the first number of ordered permutations of bits associated with the at least two subsets of bits (e.g., 613 in FIG. 6).

In aspects, to generate (at 508) (e.g., at 614, 618 in FIG. 6) the set of decoded bits (e.g., 607 in FIG. 6), first network device 502 may be configured to: (1) identify (e.g., at 616 in FIG. 6) a bit to be decoded from the set of bits (e.g., 606 in FIG. 6) based on: a match of the bit to be decoded between one of the first number of ordered permutations of bits and the at least two subsets of bits (e.g., 613 in FIG. 6), and the bit priority, (2) generate (e.g., at 614, 618 in FIG. 6) a decoded bit by decoding (e.g., being configured to decode (e.g., at 618 in FIG. 6; e.g., by 603 in FIG. 6) the bit to be decoded, and (3) remove (e.g., at 620 in FIG. 6) the decoded bit from the at least two subsets of bits (e.g., 613 in FIG. 6). In such aspects, the first network device 502 may be configured to repeat (1) to (3) for each bit in the set of bits. That is, the first network device 502 may be configured to iterate over the set of bits and perform the identification (e.g., at 616 in FIG. 6), the generation (e.g., at 614, 618 in FIG. 6), and the removal (e.g., at 620 in FIG. 6) for each bit in the set of bits (e.g., 606 in FIG. 6) for subsequent iterations.

In aspects, to generate (at 508) (e.g., at 614, 618 in FIG. 6) the set of decoded bits (e.g., 607 in FIG. 6; 707 in FIG. 7), first network device 502 may be configured to identify (e.g., at 712 in FIG. 7) the set of information bits based on a second error metric (e.g., 722 in FIG. 7) in each bit (e.g., 707′ in FIG. 7) of the set of decoded bits (e.g., 607 in FIG. 6; 707 in FIG. 7). In such aspects, the second error metric (e.g., 722 in FIG. 7) may be a reliability metric associated with bit locations (e.g., for 707′ in FIG. 7) of the set of decoded bits (e.g., 607 in FIG. 6; 707 in FIG. 7). Additionally, in such aspects, a code rate for the decoding of each bit (e.g., 707′ in FIG. 7) in the set of bits (e.g., 707 in FIG. 7) may be based on a ratio of a number of information bits in the set of information bits to a total number of bits (e.g., N in FIG. 7) in the set of bits (e.g., 706 in FIG. 7). To identify (e.g., 712 in FIG. 7) the set of information bits based on the second error metric (e.g., 722 in FIG. 7) in each bit (e.g., 707′ in FIG. 7) of the set of decoded bits (e.g., 607 in FIG. 6; 707 in FIG. 7), the first network device 502 may be configured to calculate a second number of bits for the set of frozen bits as a difference between the total number of bits (e.g., N in FIG. 7) in the set of bits (e.g., 706 in FIG. 7) and the number of information bits. Accordingly, the first network device 502 may be configured to identify (e.g., at 710 in FIG. 7) the set of frozen bits as the second number of bits that includes a lower reliability metric associated with the bit locations (e.g., 707′ in FIG. 7) of the set of decoded bits (e.g., 607 in FIG. 6; 707 in FIG. 7) than remaining bits of the set of bits (e.g., 706 in FIG. 7), and to identify (e.g., at 712 in FIG. 7) the set of information bits as the remaining bits of the set of bits (e.g., 706 in FIG. 7). In some aspects, the decoding of each bit in the set of bits (e.g., 706 in FIG. 7) by the first network device 502 may be associated with a binary erasure channel (BEC), an additive white Gaussian noise (AWGN) channel, a binary symmetric channel (BSC), and/or the like.

At 906, the first network device transmits, for a second network device, a set of encoded bits that are based on an encoding of the set of decoded bits. As an example, the transmission/provision may be performed by one or more of the component 198, the transceiver(s) 1122, and/or the antenna 1180 in FIG. 11, and or may be performed by one or more of the component 199, the transceiver(s) 1246, and/or the antenna 1280 in FIG. 12. FIG. 5 illustrates, in the context of FIGS. 6, 7, 8, an example of the first network device 502 transmitting such a set of encoded bits to the second network device 504 (e.g., a UE, a base station, etc.).

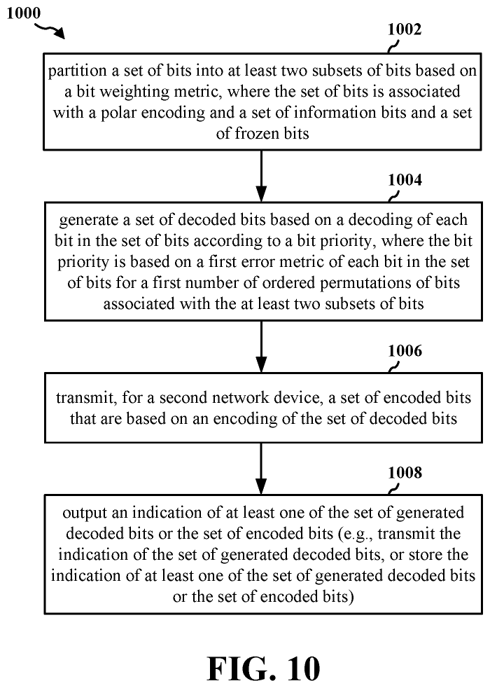

The first network device 502 may be configured to transmit, for the second network device 504, a set of encoded bits 510 that are based on an encoding (e.g., 602, 605 in FIG. 6) of the set of decoded bits (e.g., 607 in FIG. 6; 707 in FIG. 7). For example, when the first network device 502 is a UE, such a UE may be configured to transmit the set of encoded bits 510 that are based on the encoding of the set of decoded bits to a base station. As another example, when the first network device 502 is a base station, such a base station may be configured to transmit the set of encoded bits 510 that are based on the encoding of the set of decoded bits to a UE. In aspects, the network device may be configured to output an indication (e.g., 510 in FIG. 5; 608 in FIG. 6) of at least one of the set of generated decoded bits or the set of encoded bits. In such aspects, the first network device 502 may be configured to transmit the indication (e.g., 510 in FIG. 5; 608 in FIG. 6) of the set of generated decoded bits and/or to store the indication of at least one of the set of generated decoded bits or the set of encoded bits. In such aspects, storing the indication or the set of encoded bits may include storing in at least one memory of the first network device 502. FIG. 10 is a flowchart 1000 of a method of wireless communication. The method may be performed by a first network device (e.g., the first network device 502; the polar encoder/decoder 602; the decoder 702, the list decoder 802; the UE 104; the apparatus 1104; the base station 102; the network entity 1102, 1202). In some aspects, the method may include aspects described in connection with the communication flow in FIG. 5, and/or aspects described in FIGS. 4, 6, 7, 8. The method may be for dynamic frozen polar codes for probabilistic shaping. The method may improve error probabilities for bits in communication payloads and provide for optimizations and enhancements such as decoder-specific optimizations through code construction for faster/more efficient polarization, extensibility to other types of decoding (e.g., list decoding), the implementation of CRC, scaling to blocks with larger numbers of bits for communication payloads, and avoidance of disproportionate decoding steps for increasing numbers of bits encoded.

At 1002, the first network device partitions a set of bits into at least two subsets of bits based on a bit weighting metric, where the set of bits is associated with a polar encoding and a set of information bits and a set of frozen bits. As an example, the partitioning may be performed by one or more of the component 198, the transceiver(s) 1122, and/or the antenna 1180 in FIG. 11, and/or may be performed by one or more of the component 199, the transceiver(s) 1246, and/or the antenna 1280 in FIG. 12. FIG. 5 illustrates, in the context of FIGS. 6, 7, 8, an example of the first network device 502 (e.g., a UE, a base station, etc.) partitioning such a set of bits into subsets.

The first network device 502 may be configured to partition (at 506) (e.g., 612 in FIG. 6) a set of bits (e.g., 606 in FIG. 6) into at least two subsets of bits (e.g., 613 in FIG. 6) based on a bit weighting metric, where the set of bits (e.g., 606 in FIG. 6) is associated with a polar encoding (e.g., 602, 605 in FIG. 6) and a set of information bits and a set of frozen bits. The set of bits (e.g., 606 in FIG. 6) may be a block or other set of bits associated with a communication payload in accordance with polar coding with efficient polarization and dynamic decoding order. In aspects, the set of bits (e.g., 606 in FIG. 6) may include a total number of bits (e.g., N in FIG. 6), and the at least two subsets of bits (e.g., 613 in FIG. 6) may include a second number of subsets that is one more than a base-two logarithm value (e.g., the number of subsets equals n+1, or equals 1+log₂ N, where N is the total number of bits or block length and n=log₂ N). In aspects, the bit weighting metric may be a Hamming weight associated with a generator matrix for the polar code. Similarly, each bit included in a respective subset of the at least two subsets of bits (e.g., 613 in FIG. 6) may have a same Hamming weight (e.g., {n, n−1, . . . , 0}).

At 1004, the first network device generates a set of decoded bits based on a decoding of each bit in the set of bits according to a bit priority, where the bit priority is based on a first error metric of each bit in the set of bits for a first number of ordered permutations of bits associated with the at least two subsets of bits. As an example, the generation may be performed by one or more of the component 198, the transceiver(s) 1122, and/or the antenna 1180 in FIG. 11, and/or may be performed by one or more of the component 199, the transceiver(s) 1246, and/or the antenna 1280 in FIG. 12. FIG. 5 illustrates, in the context of FIGS. 6, 7, 8, an example of the first network device 502 generating such a set of decoded bits based on a decoding of each bit in the set of bits according to a bit priority.

The first network device 502 may be configured to generate (at 508) a set of decoded bits (e.g., 607 in FIG. 6) based on a decoding (e.g., by 603 in FIG. 6) of each bit in the set of bits (e.g., 606 in FIG. 6) according to a bit priority, where the bit priority is based on a first error metric (e.g., 622 in FIG. 6) of each bit in the set of bits (e.g., 606 in FIG. 6) for a first number of ordered permutations of bits associated with the at least two subsets of bits (e.g., 613 in FIG. 6). The first error metric (e.g., 622 in FIG. 6) may be a smallest log likelihood ratio and/or a largest path metric, and to generate (at 508) the set of decoded bits (e.g., 607 in FIG. 6), the first network device 502 may be configured to identify (e.g., at 610 in FIG. 6) each of the first number of ordered permutations of bits associated with the at least two subsets of bits (e.g., 613 in FIG. 6).

In aspects, to generate (at 508) (e.g., at 614, 618 in FIG. 6) the set of decoded bits (e.g., 607 in FIG. 6), first network device 502 may be configured to: (1) identify (e.g., at 616 in FIG. 6) a bit to be decoded from the set of bits (e.g., 606 in FIG. 6) based on: a match of the bit to be decoded between one of the first number of ordered permutations of bits and the at least two subsets of bits (e.g., 613 in FIG. 6), and the bit priority, (2) generate (e.g., at 614, 618 in FIG. 6) a decoded bit by decoding (e.g., being configured to decode (e.g., at 618 in FIG. 6; e.g., by 603 in FIG. 6) the bit to be decoded, and (3) remove (e.g., at 620 in FIG. 6) the decoded bit from the at least two subsets of bits (e.g., 613 in FIG. 6). In such aspects, the first network device 502 may be configured to repeat (1) to (3) for each bit in the set of bits. That is, the first network device 502 may be configured to iterate over the set of bits and perform the identification (e.g., at 616 in FIG. 6), the generation (e.g., at 614, 618 in FIG. 6), and the removal (e.g., at 620 in FIG. 6) for each bit in the set of bits (e.g., 606 in FIG. 6) for subsequent iterations.

In aspects, to generate (at 508) (e.g., at 614, 618 in FIG. 6) the set of decoded bits (e.g., 607 in FIG. 6; 707 in FIG. 7), first network device 502 may be configured to identify (e.g., at 712 in FIG. 7) the set of information bits based on a second error metric (e.g., 722 in FIG. 7) in each bit (e.g., 707′ in FIG. 7) of the set of decoded bits (e.g., 607 in FIG. 6; 707 in FIG. 7). In such aspects, the second error metric (e.g., 722 in FIG. 7) may be a reliability metric associated with bit locations (e.g., for 707′ in FIG. 7) of the set of decoded bits (e.g., 607 in FIG. 6; 707 in FIG. 7). Additionally, in such aspects, a code rate for the decoding of each bit (e.g., 707′ in FIG. 7) in the set of bits (e.g., 707 in FIG. 7) may be based on a ratio of a number of information bits in the set of information bits to a total number of bits (e.g., N in FIG. 7) in the set of bits (e.g., 706 in FIG. 7). To identify (e.g., 712 in FIG. 7) the set of information bits based on the second error metric (e.g., 722 in FIG. 7) in each bit (e.g., 707′ in FIG. 7) of the set of decoded bits (e.g., 607 in FIG. 6; 707 in FIG. 7), the first network device 502 may be configured to calculate a second number of bits for the set of frozen bits as a difference between the total number of bits (e.g., N in FIG. 7) in the set of bits (e.g., 706 in FIG. 7) and the number of information bits. Accordingly, the first network device 502 may be configured to identify (e.g., at 710 in FIG. 7) the set of frozen bits as the second number of bits that includes a lower reliability metric associated with the bit locations (e.g., 707′ in FIG. 7) of the set of decoded bits (e.g., 607 in FIG. 6; 707 in FIG. 7) than remaining bits of the set of bits (e.g., 706 in FIG. 7), and to identify (e.g., at 712 in FIG. 7) the set of information bits as the remaining bits of the set of bits (e.g., 706 in FIG. 7). In some aspects, the decoding of each bit in the set of bits (e.g., 706 in FIG. 7) by the first network device 502 may be associated with a binary erasure channel (BEC), an additive white Gaussian noise (AWGN) channel, a binary symmetric channel (BSC), and/or the like.

At 1006, the first network device transmits, for a second network device, a set of encoded bits that are based on an encoding of the set of decoded bits. As an example, the transmission/provision may be performed by one or more of the component 198, the transceiver(s) 1122, and/or the antenna 1180 in FIG. 11, and or may be performed by one or more of the component 199, the transceiver(s) 1246, and/or the antenna 1280 in FIG. 12. FIG. 5 illustrates, in the context of FIGS. 6, 7, 8, an example of the first network device 502 transmitting such a set of encoded bits to the second network device 504 (e.g., a UE, a base station, etc.).

The first network device 502 may be configured to transmit, for the second network device 504, a set of encoded bits 510 that are based on an encoding (e.g., 602, 605 in FIG. 6) of the set of decoded bits (e.g., 607 in FIG. 6; 707 in FIG. 7). For example, when the first network device 502 is a UE, such a UE may be configured to transmit the set of encoded bits 510 that are based on the encoding of the set of decoded bits to a base station. As another example, when the first network device 502 is a base station, such a base station may be configured to transmit the set of encoded bits 510 that are based on the encoding of the set of decoded bits to a UE.

At 1008, the first network device outputs an indication of at least one of the set of generated decoded bits or the set of encoded bits. As an example, the transmission/provision may be performed by one or more of the component 198, the transceiver(s) 1122, and/or the antenna 1180 in FIG. 11, and or may be performed by one or more of the component 199, the transceiver(s) 1246, and/or the antenna 1280 in FIG. 12. FIG. 5 illustrates, in the context of FIGS. 6, 7, 8, an example of the first network device 502 transmitting such a set of encoded bits to the second network device 504 (e.g., a UE, a base station, etc.).

In aspects, the network device may be configured to output an indication (e.g., 510 in FIG. 5; 608 in FIG. 6) of at least one of the set of generated decoded bits or the set of encoded bits. In such aspects, the first network device 502 may be configured to transmit the indication (e.g., 510 in FIG. 5; 608 in FIG. 6) of the set of generated decoded bits and/or to store the indication of at least one of the set of generated decoded bits or the set of encoded bits. In such aspects, storing the indication or the set of encoded bits may include storing in at least one memory of the first network device 502.

FIG. 11 is a diagram 1100 illustrating an example of a hardware implementation for an apparatus 1104. The apparatus 1104 may be a UE, a component of a UE, or may implement UE functionality. In some aspects, the apparatus 1104 may include at least one cellular baseband processor 1124 (also referred to as a modem) coupled to one or more transceivers 1122 (e.g., cellular RF transceiver). The cellular baseband processor(s) 1124 may include at least one on-chip memory 1124′. In some aspects, the apparatus 1104 may further include one or more subscriber identity modules (SIM) cards 1120 and at least one application processor 1106 coupled to a secure digital (SD) card 1108 and a screen 1110. The application processor(s) 1106 may include on-chip memory 1106′. In some aspects, the apparatus 1104 may further include a Bluetooth module 1112, a WLAN module 1114, an SPS module 1116 (e.g., GNSS module), one or more sensor modules 1118 (e.g., barometric pressure sensor/altimeter; motion sensor such as inertial measurement unit (IMU), gyroscope, and/or accelerometer(s); light detection and ranging (LIDAR), radio assisted detection and ranging (RADAR), sound navigation and ranging (SONAR), magnetometer, audio and/or other technologies used for positioning), additional memory modules 1126, a power supply 1130, and/or a camera 1132. The Bluetooth module 1112, the WLAN module 1114, and the SPS module 1116 may include an on-chip transceiver (TRX) (or in some cases, just a receiver (RX)). The Bluetooth module 1112, the WLAN module 1114, and the SPS module 1116 may include their own dedicated antennas and/or utilize the antennas 1180 for communication. The cellular baseband processor(s) 1124 communicates through the transceiver(s) 1122 via one or more antennas 1180 with the UE 104 and/or with an RU associated with a network entity 1102. The cellular baseband processor(s) 1124 and the application processor(s) 1106 may each include a computer-readable medium/memory 1124′, 1106′, respectively. The additional memory modules 1126 may also be considered a computer-readable medium/memory. Each computer-readable medium/memory 1124′, 1106′, 1126 may be non-transitory. The cellular baseband processor(s) 1124 and the application processor(s) 1106 are each responsible for general processing, including the execution of software stored on the computer-readable medium/memory. The software, when executed by the cellular baseband processor(s) 1124/application processor(s) 1106, causes the cellular baseband processor(s) 1124/application processor(s) 1106 to perform the various functions described supra. The cellular baseband processor(s) 1124 and the application processor(s) 1106 are configured to perform the various functions described supra based at least in part of the information stored in the memory. That is, the cellular baseband processor(s) 1124 and the application processor(s) 1106 may be configured to perform a first subset of the various functions described supra without information stored in the memory and may be configured to perform a second subset of the various functions described supra based on the information stored in the memory. The computer-readable medium/memory may also be used for storing data that is manipulated by the cellular baseband processor(s) 1124/application processor(s) 1106 when executing software. The cellular baseband processor(s) 1124/application processor(s) 1106 may be a component of the UE 350 and may include the at least one memory 360 and/or at least one of the TX processor 368, the RX processor 356, and the controller/processor 359. In one configuration, the apparatus 1104 may be at least one processor chip (modem and/or application) and include just the cellular baseband processor(s) 1124 and/or the application processor(s) 1106, and in another configuration, the apparatus 1104 may be the entire UE (e.g., see UE 350 of FIG. 3) and include the additional modules of the apparatus 1104.

As discussed supra, the component 198 may be configured to partition a set of bits into at least two subsets of bits based on a bit weighting metric, where the set of bits is associated with a polar encoding and a set of information bits and a set of frozen bits. The component 198 may be configured to generate a set of decoded bits based on a decoding of each bit in the set of bits according to a bit priority, where the bit priority is based on a first error metric of each bit in the set of bits for a first number of ordered permutations of bits associated with the at least two subsets of bits. The component 198 may be configured to transmit, for a second network device, a set of encoded bits that are based on an encoding of the set of decoded bits. The component 198 may be configured to output an indication of at least one of the set of generated decoded bits or the set of encoded bits. The component 198 may be further configured to perform any of the aspects described in connection with the flowcharts in any of FIGS. 9, 10, and/or any of the aspects performed by a first network device (e.g., a UE, etc.) for any of FIGS. 4-8. The component 198 may be within the cellular baseband processor(s) 1124, the application processor(s) 1106, or both the cellular baseband processor(s) 1124 and the application processor(s) 1106. The component 198 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. As shown, the apparatus 1104 may include a variety of components configured for various functions. In one configuration, the apparatus 1104, and in particular the cellular baseband processor(s) 1124 and/or the application processor(s) 1106, may include means for partitioning a set of bits into at least two subsets of bits based on a bit weighting metric, where the set of bits is associated with a polar encoding and a set of information bits and a set of frozen bits. In one configuration, the apparatus 1104, and in particular the cellular baseband processor(s) 1124 and/or the application processor(s) 1106, may include means for generating a set of decoded bits based on a decoding of each bit in the set of bits according to a bit priority, where the bit priority is based on a first error metric of each bit in the set of bits for a first number of ordered permutations of bits associated with the at least two subsets of bits. In one configuration, the apparatus 1104, and in particular the cellular baseband processor(s) 1124 and/or the application processor(s) 1106, may include means for transmitting, for a second network device, a set of encoded bits that are based on an encoding of the set of decoded bits. In one configuration, the apparatus 1104, and in particular the cellular baseband processor(s) 1124 and/or the application processor(s) 1106, may include means for outputting an indication of at least one of the set of generated decoded bits or the set of encoded bits. The means may be the component 198 of the apparatus 1104 configured to perform the functions recited by the means. As described supra, the apparatus 1104 may include the TX processor 368, the RX processor 356, and the controller/processor 359. As such, in one configuration, the means may be the TX processor 368, the RX processor 356, and/or the controller/processor 359 configured to perform the functions recited by the means.

FIG. 12 is a diagram 1200 illustrating an example of a hardware implementation for a network entity 1202. The network entity 1202 may be a BS, a component of a BS, or may implement BS functionality. The network entity 1202 may include at least one of a CU 1210, a DU 1230, or an RU 1240. For example, depending on the layer functionality handled by the component 199, the network entity 1202 may include the CU 1210; both the CU 1210 and the DU 1230; each of the CU 1210, the DU 1230, and the RU 1240; the DU 1230; both the DU 1230 and the RU 1240; or the RU 1240. The CU 1210 may include at least one CU processor 1212. The CU processor(s) 1212 may include on-chip memory 1212′. In some aspects, the CU 1210 may further include additional memory modules 1214 and a communications interface 1218. The CU 1210 communicates with the DU 1230 through a midhaul link, such as an F1 interface. The DU 1230 may include at least one DU processor 1232. The DU processor(s) 1232 may include on-chip memory 1232′. In some aspects, the DU 1230 may further include additional memory modules 1234 and a communications interface 1238. The DU 1230 communicates with the RU 1240 through a fronthaul link. The RU 1240 may include at least one RU processor 1242. The RU processor(s) 1242 may include on-chip memory 1242′. In some aspects, the RU 1240 may further include additional memory modules 1244, one or more transceivers 1246, antennas 1280, and a communications interface 1248. The RU 1240 communicates with the UE 104. The on-chip memory 1212′, 1232′, 1242′ and the additional memory modules 1214, 1234, 1244 may each be considered a computer-readable medium/memory. Each computer-readable medium/memory may be non-transitory. Each of the processors 1212, 1232, 1242 is responsible for general processing, including the execution of software stored on the computer-readable medium/memory. The software, when executed by the corresponding processor(s) causes the processor(s) to perform the various functions described supra. The computer-readable medium/memory may also be used for storing data that is manipulated by the processor(s) when executing software.

As discussed supra, the component 199 may be configured to partition a set of bits into at least two subsets of bits based on a bit weighting metric, where the set of bits is associated with a polar encoding and a set of information bits and a set of frozen bits. The component 199 may be configured to generate a set of decoded bits based on a decoding of each bit in the set of bits according to a bit priority, where the bit priority is based on a first error metric of each bit in the set of bits for a first number of ordered permutations of bits associated with the at least two subsets of bits. The component 199 may be configured to transmit, for a second network device, a set of encoded bits that are based on an encoding of the set of decoded bits. The component 199 may be configured to output an indication of at least one of the set of generated decoded bits or the set of encoded bits. The component 199 may be further configured to perform any of the aspects described in connection with the flowcharts in any of FIGS. 9, 10, and/or any of the aspects performed by a first network device (e.g., a network node/entity, etc.) for any of FIGS. 4-8. The component 199 may be within one or more processors of one or more of the CU 1210, DU 1230, and the RU 1240. The component 199 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. The network entity 1202 may include a variety of components configured for various functions. In one configuration, the network entity 1202 may include means for partitioning a set of bits into at least two subsets of bits based on a bit weighting metric, where the set of bits is associated with a polar encoding and a set of information bits and a set of frozen bits. In one configuration, the network entity 1202 may include means for generating a set of decoded bits based on a decoding of each bit in the set of bits according to a bit priority, where the bit priority is based on a first error metric of each bit in the set of bits for a first number of ordered permutations of bits associated with the at least two subsets of bits. In one configuration, the network entity 1202 may include means for transmitting, for a second network device, a set of encoded bits that are based on an encoding of the set of decoded bits. In one configuration, the network entity 1202 may include means for outputting an indication of at least one of the set of generated decoded bits or the set of encoded bits. The means may be the component 199 of the network entity 1202 configured to perform the functions recited by the means. As described supra, the network entity 1202 may include the TX processor 316, the RX processor 370, and the controller/processor 375. As such, in one configuration, the means may be the TX processor 316, the RX processor 370, and/or the controller/processor 375 configured to perform the functions recited by the means.

Communications between network nodes (e.g., base stations, gNBs, etc.) and UEs, or transmitter network devices and receiver network devices, generally, may utilize polar codes for channel polarization of communication payloads. A polar code is based on the phenomenon of channel polarization, where communication channels, after applying the polar transform (e.g., with an Arikan kernel), may converge to either of a useless or a noiseless channel. Polar code design may include determining which bit locations are allocated to send information bits and which bit locations to send frozen bits. SC decoding (e.g., with a fixed decoding order) and SCL decoding are common decoding algorithms that may be used for polar code implementations. However, fixed decoding order solutions are limited to bit-by-bit sequential decoding of fixed-position bits in a block to be polar encoded for a communication payload. Such fixed order decoding lacks mechanisms to improve error probabilities for bits in communication payloads. Additionally, fixed order decoding may have issues with optimizations and enhancements such as decoder-specific optimizations through code construction for faster/more efficient polarization, extensibility to other types of decoding (e.g., list decoding), the implementation of CRC, scaling to blocks with larger numbers of bits for communication payloads, and avoidance of disproportionate decoding steps for increasing numbers of bits encoded.

Aspects described herein for polar coding with efficient polarization and dynamic decoding orders provide solutions to such issues. Aspects enable a polar code to be decoded with a different decoding order (that preserves the polar code, e.g., via automorphism ensemble decoding), and by which the decoding results may depend on the decoding order by utilizing permutation-based polar decoding using automorphisms. Aspects enable a decoder to decode the same received signal in accordance with different decoding orders (e.g., permutations) and more efficiently identify the best result from specific subsets of these permutations by utilizing permutation-based polar decoding using automorphisms. Aspects enable a polar decoder to perform a faster polarization than conventional polar codes by utilizing automorphism in polar code construction and decoder characteristics.

It is understood that the specific order or hierarchy of blocks in the processes/flowcharts disclosed is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not limited to the aspects described herein, but are to be accorded the full scope consistent with the language claims. Reference to an element in the singular does not mean “one and only one” unless specifically so stated, but rather “one or more.” Terms such as “if,” “when,” and “while” do not imply an immediate temporal relationship or reaction. That is, these phrases, e.g., “when,” do not imply an immediate action in response to or during the occurrence of an action, but simply imply that if a condition is met then an action will occur, but without requiring a specific or immediate time constraint for the action to occur. The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. Sets should be interpreted as a set of elements where the elements number one or more. Accordingly, for a set of X, X would include one or more elements. When at least one processor is configured to perform a set of functions, the at least one processor, individually or in any combination, is configured to perform the set of functions. Accordingly, each processor of the at least one processor may be configured to perform a particular subset of the set of functions, where the subset is the full set, a proper subset of the set, or an empty subset of the set. A processor may be referred to as processor circuitry. A memory/memory module may be referred to as memory circuitry. If a first apparatus receives data from or transmits data to a second apparatus, the data may be received/transmitted directly between the first and second apparatuses, or indirectly between the first and second apparatuses through a set of apparatuses. A device configured to “output” data or “provide” data, such as a transmission, signal, or message, may transmit the data, for example with a transceiver, or may send the data to a device that transmits the data. A device configured to “obtain” data, such as a transmission, signal, or message, may receive, for example with a transceiver, or may obtain the data from a device that receives the data. Information stored in a memory includes instructions and/or data. All structural and functional equivalents to the elements of the various aspects described throughout this disclosure that are known or later come to be known to those of ordinary skill in the art are expressly incorporated herein by reference and are encompassed by the claims. Moreover, nothing disclosed herein is dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

As used herein, the phrase “based on” shall not be construed as a reference to a closed set of information, one or more conditions, one or more factors, or the like. In other words, the phrase “based on A” (where “A” may be information, a condition, a factor, or the like) shall be construed as “based at least on A” unless specifically recited differently.

The following aspects are illustrative only and may be combined with other aspects or teachings described herein, without limitation.
Aspect 1. A method of wireless communication at a first network device, comprising: partitioning a set of bits into at least two subsets of bits based on a bit weighting metric, wherein the set of bits is associated with a polar encoding and a set of information bits and a set of frozen bits; generating a set of decoded bits based on a decoding of each bit in the set of bits according to a bit priority, wherein the bit priority is based on a first error metric of each bit in the set of bits for a first number of ordered permutations of bits associated with the at least two subsets of bits; and transmitting, for a second network device, a set of encoded bits that are based on an encoding of the set of decoded bits.
Aspect 2. The method of aspect 1, wherein the set of bits includes a total number of bits, and wherein the at least two subsets of bits include a second number of subsets that is one more than a base-two logarithm value of the total number of bits.
Aspect 3. The method of aspect 1, wherein the bit weighting metric is a Hamming weight associated with a generator matrix, and wherein each bit included in a respective subset of the at least two subsets of bits has a same Hamming weight.
Aspect 4. The method of aspect 1, wherein the first error metric is at least one of a smallest log likelihood ratio or a largest path metric.
Aspect 5. The method of aspect 1, wherein generating the set of decoded bits includes: identifying each of the first number of ordered permutations of bits associated with the at least two subsets of bits.
Aspect 6. The method of aspect 5, wherein generating the set of decoded bits includes: (1) identifying a bit to be decoded from the set of bits based on: a match of the bit to be decoded between one of the first number of ordered permutations of bits and the at least two subsets of bits, and the bit priority; (2) generating a decoded bit by decoding the bit to be decoded; and (3) removing the decoded bit from the at least two subsets of bits.
Aspect 7. The method of aspect 6, wherein generating the set of decoded bits includes repeating (1) to (3) for each bit in the set of bits.
Aspect 8. The method of aspect 1, wherein generating the set of decoded bits based on the decoding of each bit in the set of bits according to the bit priority includes: identifying the set of information bits based on a second error metric in each bit of the set of decoded bits.
Aspect 9. The method of aspect 8, wherein the second error metric is a reliability metric associated with bit locations of the set of decoded bits, and wherein a code rate for the decoding of each bit in the set of bits is based on a ratio of a number of information bits in the set of information bits to a total number of bits in the set of bits.
Aspect 10. The method of aspect 9, wherein identifying the set of information bits based on the second error metric in each bit of the set of decoded bits includes: calculating a second number of bits for the set of frozen bits as a difference between the total number of bits in the set of bits and the number of information bits; identifying the set of frozen bits as the second number of bits that includes a lower reliability metric associated with the bit locations of the set of decoded bits than remaining bits of the set of bits; and identifying the set of information bits as the remaining bits of the set of bits.
Aspect 11. The method of aspect 10, wherein the decoding of each bit in the set of bits is associated with at least one of a binary erasure channel (BEC), an additive white Gaussian noise (AWGN) channel, or a binary symmetric channel (BSC).
Aspect 12. The method of aspect 8, wherein the second error metric is at least one of a largest path metric or a cyclic redundancy check (CRC), and wherein the decoding of each bit in the set of bits is associated with a list decoding including a list size indicative of a number of paths in a list for the list decoding.
Aspect 13. The method of aspect 12, wherein identifying the set of information bits includes: generating, for each of the number of paths in the list and each information bit identified, a first path for a first bit value of the information bit identified and a second path for a second bit value of the information bit identified; identifying, for each of the number of paths in the list and each bit, each permutation for a determination of a next bit to be decoded; and identifying a set of paths based on the second error metric.
Aspect 14. The method of aspect 13, wherein the second error metric is the largest path metric, and wherein identifying the set of paths based on the second error metric includes identifying the set of paths that includes a lowest largest path metric value; or wherein the second error metric is the CRC, and wherein identifying the set of paths based on the second error metric includes identifying the set of paths that pass the CRC.
Aspect 15. The method of aspect 1, wherein the first network device is one of a user equipment (UE) or a network node and the second network device is another one of the UE or the network node.
Aspect 16. The method of aspect 1, further comprising: outputting an indication of at least one of the set of generated decoded bits or the set of encoded bits.
Aspect 17. The method of aspect 16, wherein outputting the indication of the set of generated decoded bits comprises: transmitting the indication of the set of generated decoded bits; or storing the indication of at least one of the set of generated decoded bits or the set of encoded bits.
Aspect 18. An apparatus for wireless communication at a transmitter network device, comprising: at least one memory; and at least one processor coupled to the at least one memory, the at least one processor, individually or in any combination, is configured to perform the method of any of aspects 1 to 17.
Aspect 19. An apparatus for wireless communication at a transmitter network device, comprising means for performing each step in the method of any of aspects 1 to 17.
Aspect 20. The apparatus of any of aspects 18 and 19, further comprising a transceiver configured to receive or to transmit in association with the method of any of aspects 1 to 17.
Aspect 21. A computer-readable medium (e.g., a non-transitory computer-readable medium) storing computer executable code at a transmitter network device, the code when executed by at least one processor causes the at least one processor to perform the method of any of aspects 1 to 17.

What is claimed is:

1. An apparatus for wireless communication at a first network device, comprising:
at least one memory; and
at least one processor coupled to the at least one memory and, based at least in part on information stored in the at least one memory, the at least one processor, individually or in any combination, is configured to:
partition a set of bits into at least two subsets of bits based on a bit weighting metric, wherein the set of bits is associated with a polar encoding and a set of information bits and a set of frozen bits;
generate a set of decoded bits based on a decoding of each bit in the set of bits according to a bit priority, wherein the bit priority is based on a first error metric of each bit in the set of bits for a first number of ordered permutations of bits associated with the at least two subsets of bits; and
transmit, for a second network device, a set of encoded bits that are based on an encoding of the set of decoded bits.

2. The apparatus of claim 1, wherein the set of bits includes a total number of bits, and wherein the at least two subsets of bits include a second number of subsets that is one more than a base-two logarithm value of the total number of bits.

3. The apparatus of claim 1, wherein the bit weighting metric is a Hamming weight associated with a generator matrix, and wherein each bit included in a respective subset of the at least two subsets of bits has a same Hamming weight.

4. The apparatus of claim 1, wherein the first error metric is at least one of a smallest log likelihood ratio or a largest path metric.

5. The apparatus of claim 1, wherein to generate the set of decoded bits, the at least one processor, individually or in any combination, is configured to:
identify each of the first number of ordered permutations of bits associated with the at least two subsets of bits.

6. The apparatus of claim 5, wherein to generate the set of decoded bits, the at least one processor, individually or in any combination, is configured to:
(1) identify a bit to be decoded from the set of bits based on:
a match of the bit to be decoded between one of the first number of ordered permutations of bits and the at least two subsets of bits, and
the bit priority;
(2) generate a decoded bit by decoding the bit to be decoded; and
(3) remove the decoded bit from the at least two subsets of bits.

7. The apparatus of claim 6, wherein to generate the set of decoded bits, the at least one processor, individually or in any combination, is configured to repeat (1) to (3) for each bit in the set of bits.

8. The apparatus of claim 1, wherein to generate the set of decoded bits based on the decoding of each bit in the set of bits according to the bit priority, the at least one processor, individually or in any combination, is configured to:
identify the set of information bits based on a second error metric in each bit of the set of decoded bits.

9. The apparatus of claim 8, wherein the second error metric is a reliability metric associated with bit locations of the set of decoded bits, and wherein a code rate for the decoding of each bit in the set of bits is based on a ratio of a number of information bits in the set of information bits to a total number of bits in the set of bits.

10. The apparatus of claim 9, wherein to identify the set of information bits based on the second error metric in each bit of the set of decoded bits, the at least one processor, individually or in any combination, is configured to:
calculate a second number of bits for the set of frozen bits as a difference between the total number of bits in the set of bits and the number of information bits;
identify the set of frozen bits as the second number of bits that includes a lower reliability metric associated with the bit locations of the set of decoded bits than remaining bits of the set of bits; and
identify the set of information bits as the remaining bits of the set of bits.

11. The apparatus of claim 10, wherein the decoding of each bit in the set of bits is associated with at least one of a binary erasure channel (BEC), an additive white Gaussian noise (AWGN) channel, or a binary symmetric channel (BSC).

12. The apparatus of claim 8, wherein the second error metric is at least one of a largest path metric or a cyclic redundancy check (CRC), and wherein the decoding of each bit in the set of bits is associated with a list decoding including a list size indicative of a number of paths in a list for the list decoding.

13. The apparatus of claim 12, wherein to identify the set of information bits, the at least one processor, individually or in any combination, is configured to:
generate, for each of the number of paths in the list and each information bit identified, a first path for a first bit value of the information bit identified and a second path for a second bit value of the information bit identified;
identify, for each of the number of paths in the list and each bit, each permutation for a determination of a next bit to be decoded; and
identify a set of paths based on the second error metric.

14. The apparatus of claim 13, wherein the second error metric is the largest path metric, and wherein to identify the set of paths based on the second error metric, the at least one processor, individually or in any combination, is configured to identify the set of paths that includes a lowest largest path metric value; or
wherein the second error metric is the CRC, and wherein to identify the set of paths based on the second error metric, the at least one processor, individually or in any combination, is configured to identify the set of paths that pass the CRC.

15. The apparatus of claim 1, wherein the first network device is one of a user equipment (UE) or a network node and the second network device is another one of the UE or the network node.

16. The apparatus of claim 1, wherein the at least one processor, individually or in any combination, is further configured to:
output an indication of at least one of the set of generated decoded bits or the set of encoded bits.

17. The apparatus of claim 16, wherein to output the indication of the set of generated decoded bits, the at least one processor, individually or in any combination, is configured to:
transmit the indication of the set of generated decoded bits; or
store the indication of at least one of the set of generated decoded bits or the set of encoded bits.

18. The apparatus of claim 1, further comprising at least one transceiver coupled to the at least one processor, wherein to transmit the set of encoded bits, the at least one processor, individually or in any combination, is configured to:
transmit, for the second network device and via the at least one transceiver, the set of encoded bits that are based on the encoding of the set of decoded bits.

19. A method of wireless communication at a first network device, comprising:
partitioning a set of bits into at least two subsets of bits based on a bit weighting metric, wherein the set of bits is associated with a polar encoding and a set of information bits and a set of frozen bits;
generating a set of decoded bits based on a decoding of each bit in the set of bits according to a bit priority, wherein the bit priority is based on a first error metric of each bit in the set of bits for a first number of ordered permutations of bits associated with the at least two subsets of bits; and
transmitting, for a second network device, a set of encoded bits that are based on an encoding of the set of decoded bits.

20. A computer-readable medium storing computer executable code at first network device, the code when executed by at least one processor causes the at least one processor to:
partition a set of bits into at least two subsets of bits based on a bit weighting metric, wherein the set of bits is associated with a polar encoding and a set of information bits and a set of frozen bits;
generate a set of decoded bits based on a decoding of each bit in the set of bits according to a bit priority, wherein the bit priority is based on a first error metric of each bit in the set of bits for a first number of ordered permutations of bits associated with the at least two subsets of bits; and
transmit, for a second network device, a set of encoded bits that are based on an encoding of the set of decoded bits.
